(19) United States
(12) Patent Application Publication
(10) Pub. No.: US 2024/0079495 A1
(43) Pub. Date: Mar. 7, 2024

(54) MEMORY DEVICE AND METHOD OF FABRICATING THE SAME

(71) Applicant: Taiwan Semiconductor Manufacturing Company, Ltd., Hsinchu (TW)

(72) Inventors: Marcus Johannes Henricus Van Dal, Linden (BE); Georgios Vellianitis, Heverlee (BE); Gerben DOORNBOS, Kessel-Lo (BE); Oreste Madia, Bruxelles (BE)

(73) Assignee: Taiwan Semiconductor Manufacturing Company, Ltd., Hsinchu (TW)

(21) Appl. No.: 18/152,160

(22) Filed: Jan. 10, 2023

Related U.S. Application Data
(60) Provisional application No. 63/404,173, filed on Sep. 6, 2022.

(51) Int. Cl. H01L 29/78; H01L 21/28; H01L 29/66; H01L 29/786; H01L 29/792

(52) U.S. Cl. CPC H01L 29/78391; H01L 29/40111; H01L 29/40117; H01L 29/66969; H01L 29/78648; H01L 29/7869; H01L 29/792

(57) ABSTRACT

A memory device includes a gate structure, a ferroelectric structure over and electrically connected with the gate structure, a channel structure over the ferroelectric structure, and a plurality of contact structures over the channel structure. The gate structure includes a first gate as a back gate, a second gate as a floating gate, and a tunneling layer sandwiched there-between. The plurality of contact structures is laterally spaced apart with each other by a predetermined distance. In some embodiments, the sidewalls of the first gate are aligned with sidewalls of the plurality of contact structures.

### CROSS-REFERENCE TO RELATED APPLICATION

This application claims the priority benefit of U.S. provisional application Ser. No. 63/404,173, filed on Sep. 6, 2022. The entirety of the above-mentioned patent application is hereby incorporated by reference herein and made a part of this specification.

### BACKGROUND

Many modern-day electronic devices contain electronic memory configured to store data. Electronic memory may be volatile memory or non-volatile memory. Volatile memory stores data while it is powered, while non-volatile memory is able to store data when power is removed. Emerging non-volatile memories are getting new interest in the system design. They are used to design logic-in-memory circuits and propose alternatives to von-Neumann architectures. Non-volatile memory based on ferroelectric field-effect transistor (Fe-FET) is one serious candidate for the next generation non-volatile memory technology for it reduces the number of data transfers between the system memory and the computing core. This is because Fe-FET based memory devices provide for various advantages, including a fast write speed, small read-after-write latency, high endurance, low power consumption, large memory window, and low susceptibility to damage from radiation.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1A and FIG. 1B respectively illustrate a schematic sectional view of a memory device and a top view of the memory device layout according to some embodiments of the present disclosure.

FIG. 2A and FIG. 2B respectively illustrate a schematic sectional view of a memory device and a top view of the memory device layout according to some embodiments of the present disclosure.

FIG. 3A and FIG. 3B respectively illustrate a schematic sectional view of a memory device and a top view of the memory device layout according to some embodiments of the present disclosure.

FIG. 4A and FIG. 4B respectively illustrate a schematic sectional view of a memory device and a top view of the memory device layout according to some embodiments of the present disclosure.

FIG. 5A and FIG. 5B respectively illustrate a schematic sectional view of a memory device and a top view of the memory device layout according to some embodiments of the present disclosure.

FIG. 6 is a transmission electron microscope (TEM) picture of a sectional view of the memory device, in accordance with some embodiments.

FIG. 7 is a current versus voltage curve (I-V) of the memory device, in accordance with some embodiments.

FIG. 8A to FIG. 8K are I-V curves, polarization versus voltage (P-V) curves, and gate leakage current versus voltage (J-V) curves of the schematic sectional views of the memory device during various operation stages according to some embodiments of the present disclosure.

FIG. 9A to FIG. 9W are schematic sectional views of various stages in a method of fabricating a memory device according to some embodiments of the present disclosure.

FIG. 10 is a method of fabricating a memory device according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description.

It should be appreciated that the following embodiment(s) of the disclosure provides applicable concepts that can be embodied in a wide variety of specific contexts. The specific embodiment(s) discussed herein is merely illustrative and is related to a semiconductor device including a sensor component (or device) of an ion-sensing transistor disposed in an interconnect formed during back-end-of-line (BEOL) processes, and is not intended to limit the scope of the disclosure. In accordance with some embodiments, one or more than one sensor component (or device) is embedded in an interconnect of the semiconductor device to arrive to a large sensing (or testing) area, where the sensor component (or device) is formed with a thin film transistor (TFT) having a channel of indium gallium zinc oxide (IGZO) with a gate dielectric of a high-k dielectric material. In the case, such thin film transistor is able to formed in the interconnect during the BEOL processes, thus the manufacturing process of the semiconductor device is simplified, thereby lowering the manufacturing cost.

As Von-Neumann proposed the computing architecture, the anticipated bandwidth limitation caused a performance bottleneck by the memory hierarchy design. However, aiming for various scaling purpose, processing speed versus energy consumption of the memory, the logic and main memory fabrication encountered an increasing performance gap. Further exacerbated by scaling challenges, at an increased chip area for the nonvolatile memory, the improvement for embedded nonvolatile ferroelectric memory is persistent.

In current flash memory, there is a tradeoff between the operation voltage and the retention time due to the incorporation of the thin tunneling layer in the device structure. Reducing the thickness of the tunneling oxide layer has been tried to reduce the program/erase voltage and enhance the level of integration. However, as the thickness of the tunneling oxide layer decreases, the leakage current from the floating gate becomes larger, resulting in storage information loss hence retention loss. Flash devices are envisioned to be integrated into one of the metal layers in a CMOS technology. This could lead to a cost-effective way to integrate embedded flash by saving die area and lower processing cost.

Ferroelectric field-effect transistor (FE-FET) is generally used as a single transistor, and reading of such transistor using a normal differential sense amplifier is impossible. Although using two FE-FETs to make a differential pair may be attempted, however, this consumes two times the area, and requires two complementary write operations. In the embodiments of the present disclosure, a novel embedded flash transistor technology using the back-gated TFT device configuration. However, it is noted that Fe-FET technology in the FEOL does not exist.

A standard flash cell is a floating gate structure, which comprises of a channel layer, a tunnel oxide, and a data floating gate (FG) layer surrounded by dielectrics, a control oxide, and a gate electrode. Being electrically isolated, the FG acts as the storing layer in the device. When applying a voltage on the gate electrode, electrons (holes) tunnel from the channel layer to the FG layer through the thin tunnel oxide, causing shifting in the threshold voltage (Vₜₕ). The logic states are defined by the current upon a read voltage within the window of the threshold voltage shift. This leads to a clockwise hysteresis in the current versus voltage (I-V) curve. A variant in which the floating gate is replaced by a triple dielectric, typically SiO₂/Si₃N₄/SiO₂ (oxide-nitride-oxide, ONO), and the charge is stored in trap states in the nitride.

Ferroelectric field-effect transistor with top-gate and back-gate structures have been extensively used for compatibility with the existing fabrication process. The present invention relates to a flash memory device comprising a ferroelectric fin field effect transistor having a floating back gate (or back-gate FET in a thin film transistor configuration) and methods of manufacturing the same, which are described in detail with accompanying figures.

FE-FET contains a ferroelectric layer in the gate dielectric stack of a standard metal-oxide-semiconductor field-effect transistor (MOSFET). The FE-FET is viewed as a non-volatile memory element in which binary data is stored in the direction of ferroelectric polarization (up or down). The up and down polarization directions either assist in the formation of the inversion layer in the semiconductor channel or deplete it, resulting in opposite shifts in the threshold voltage of the FE-FET. An attractive way to co-integrate with CMOS is a thin film transistor (TFT) as a part of the back-end-of-line (BEOL) processing. TFTs are attractive for BEOL integration since they can be processed at low-temperature and can add functionality to the BEOL without occupying too much valuable front-end chip area.

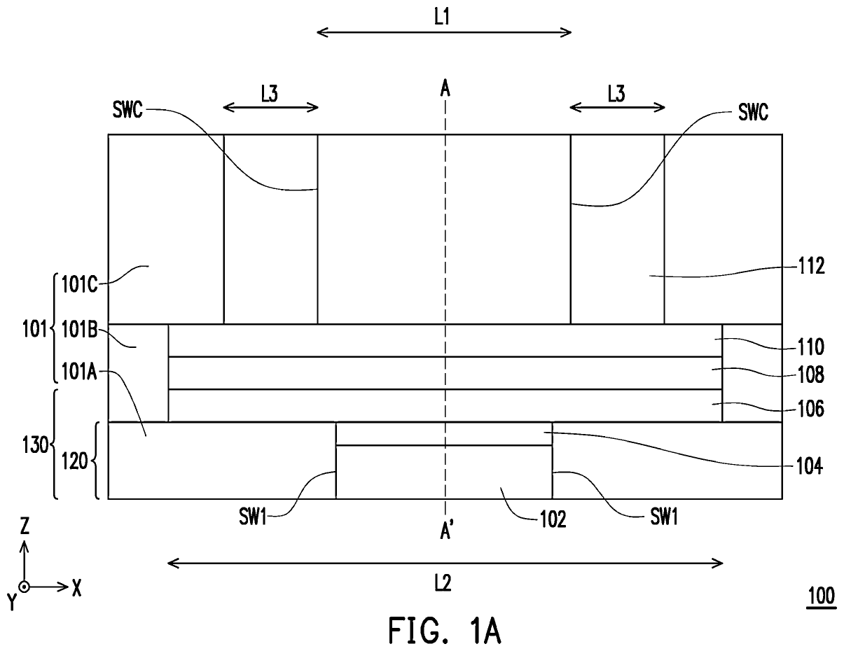

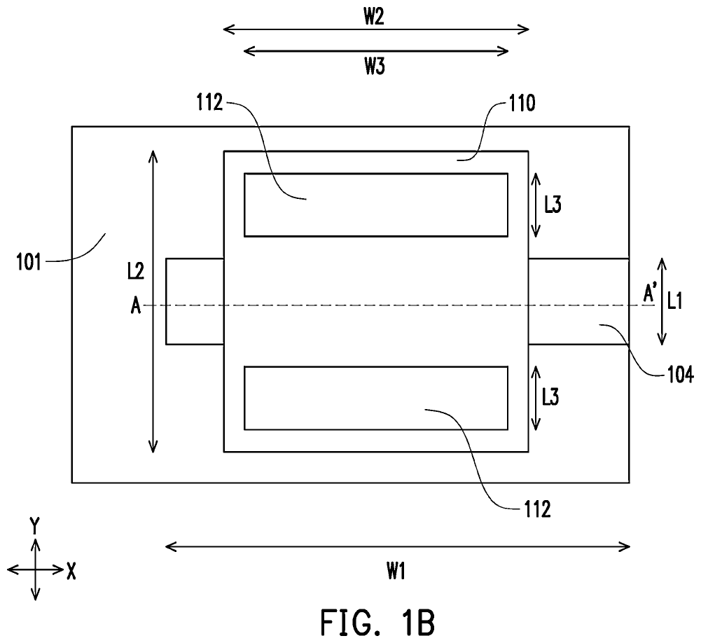

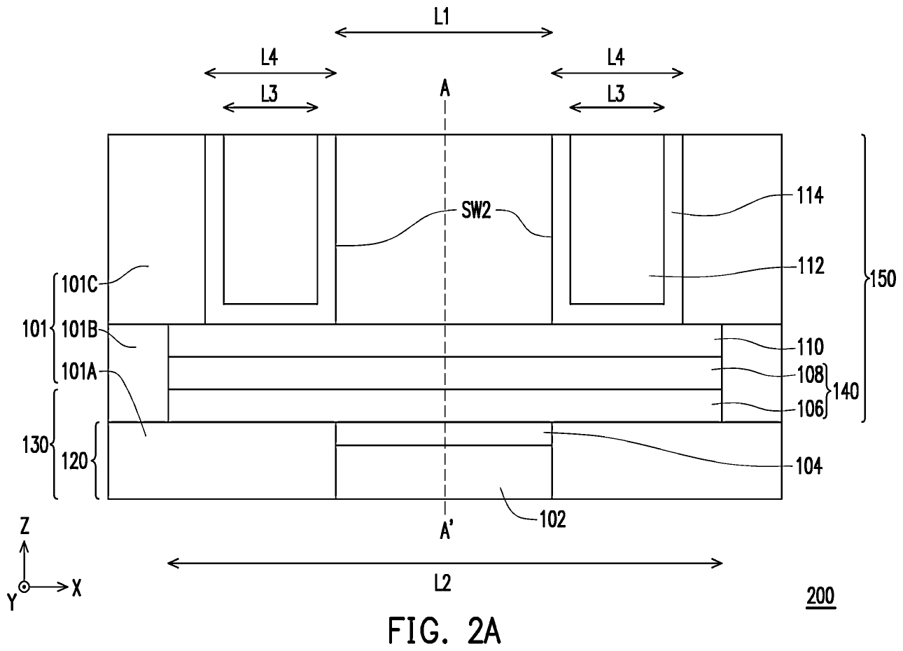

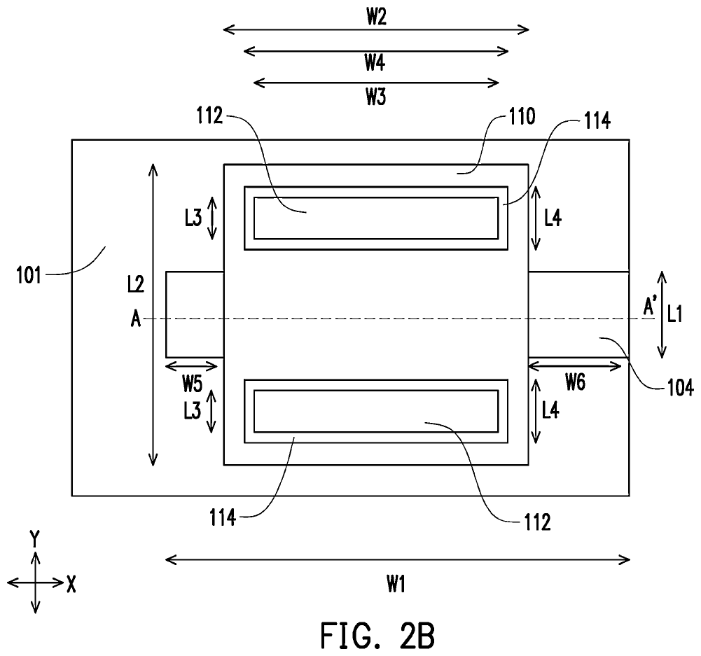

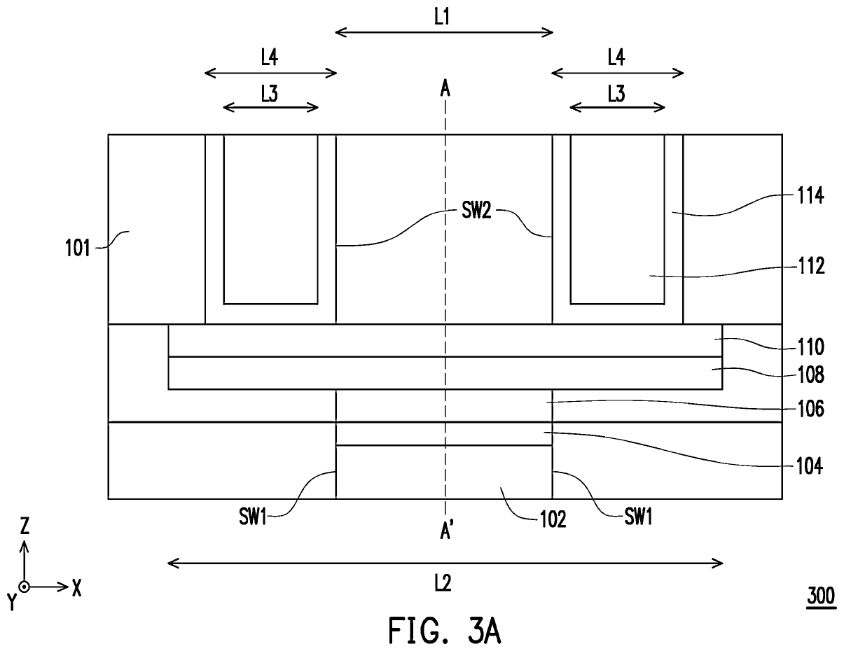

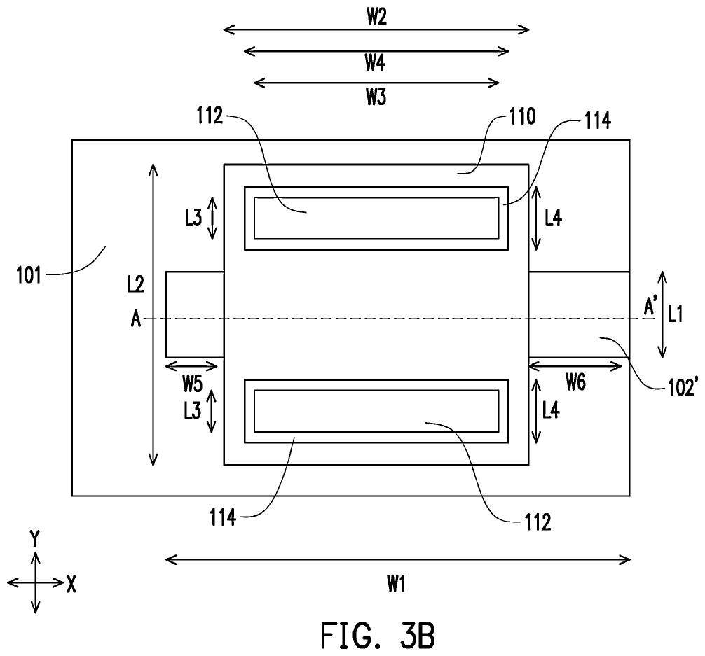

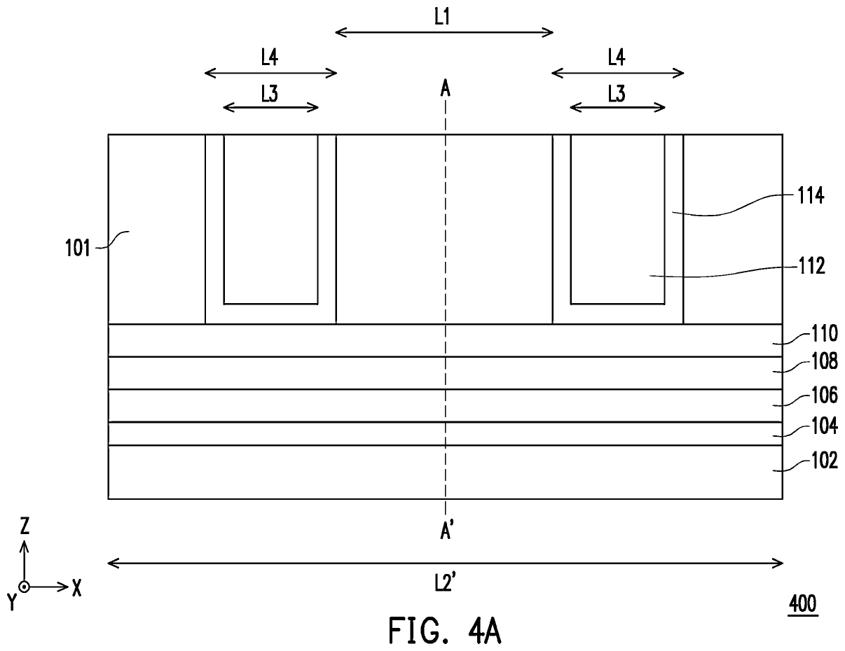

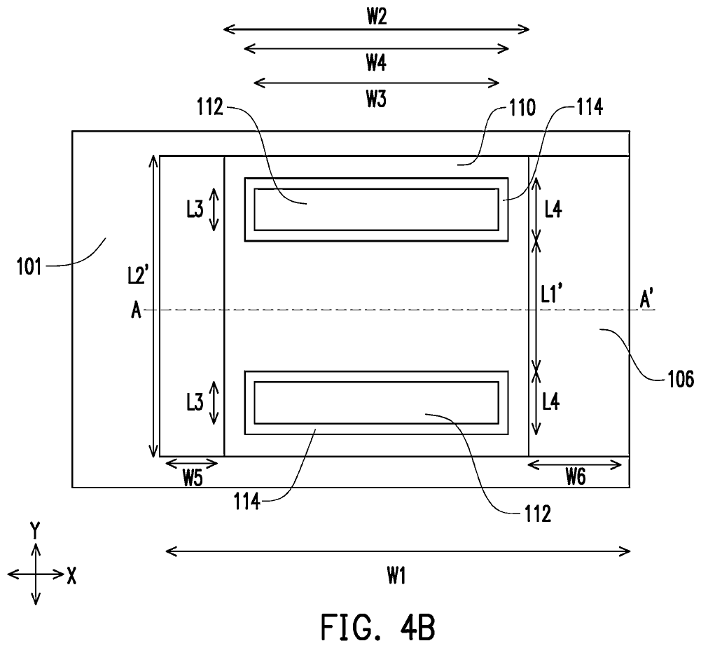

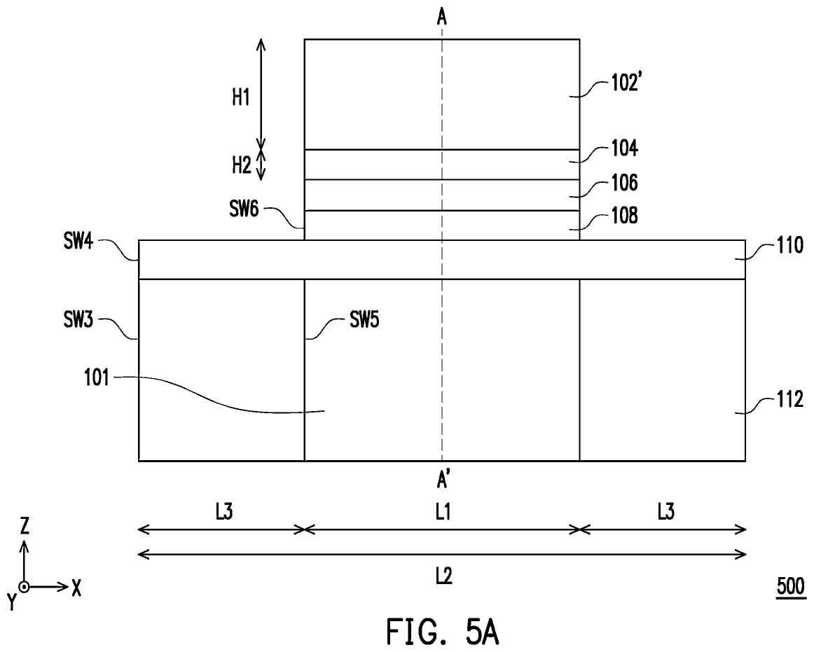

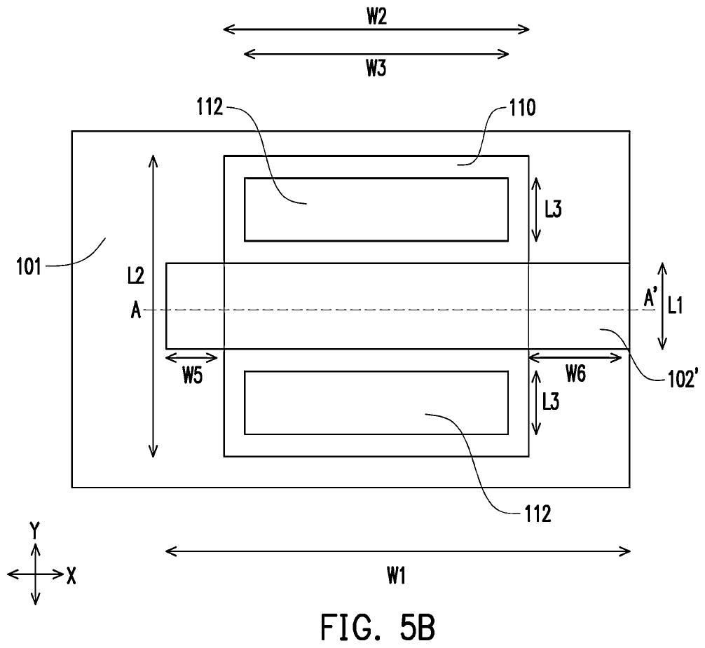

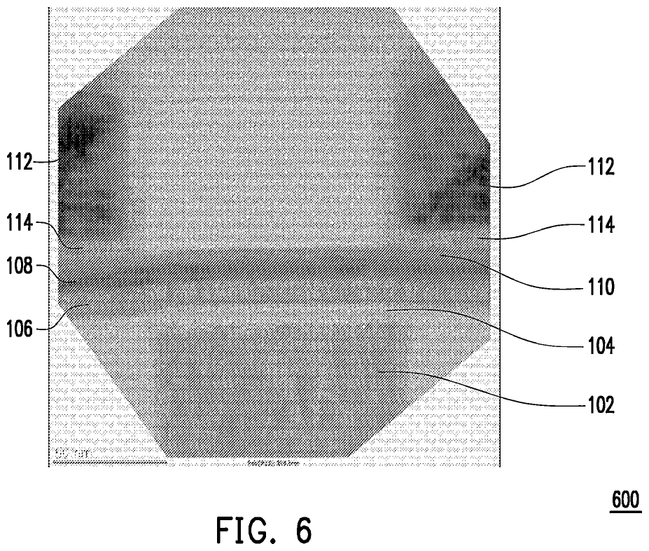

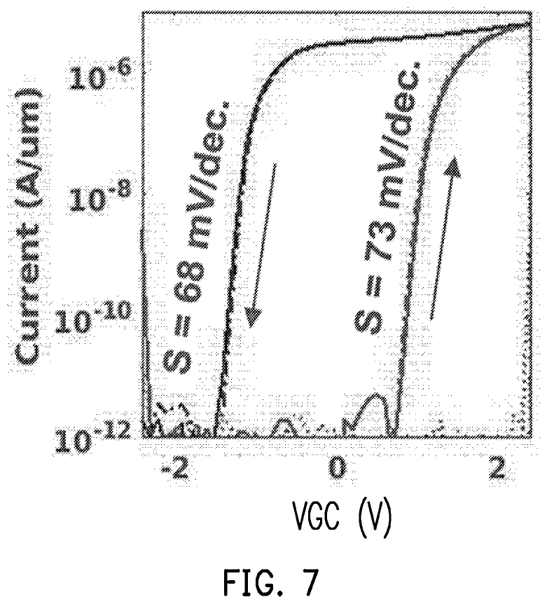

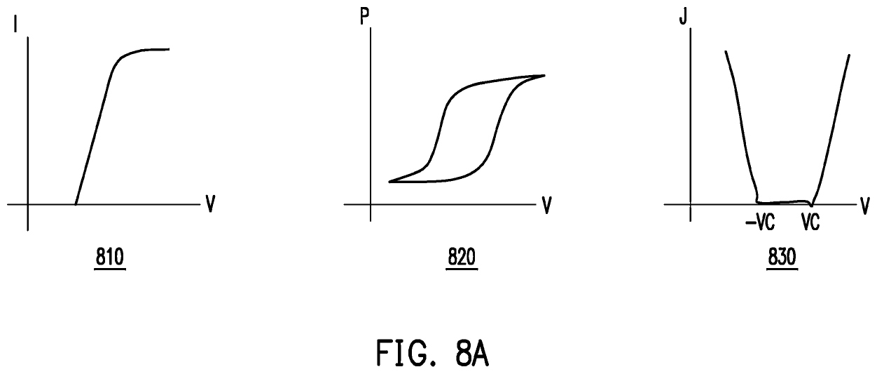

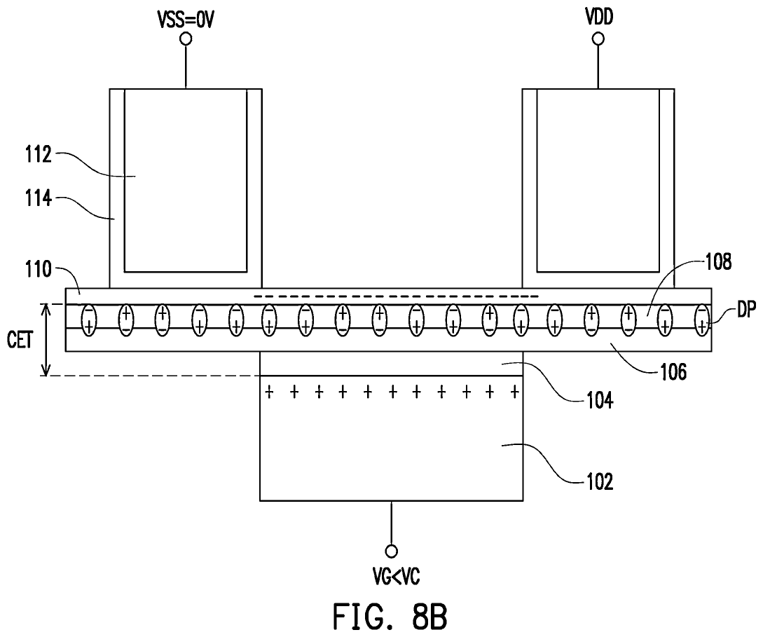

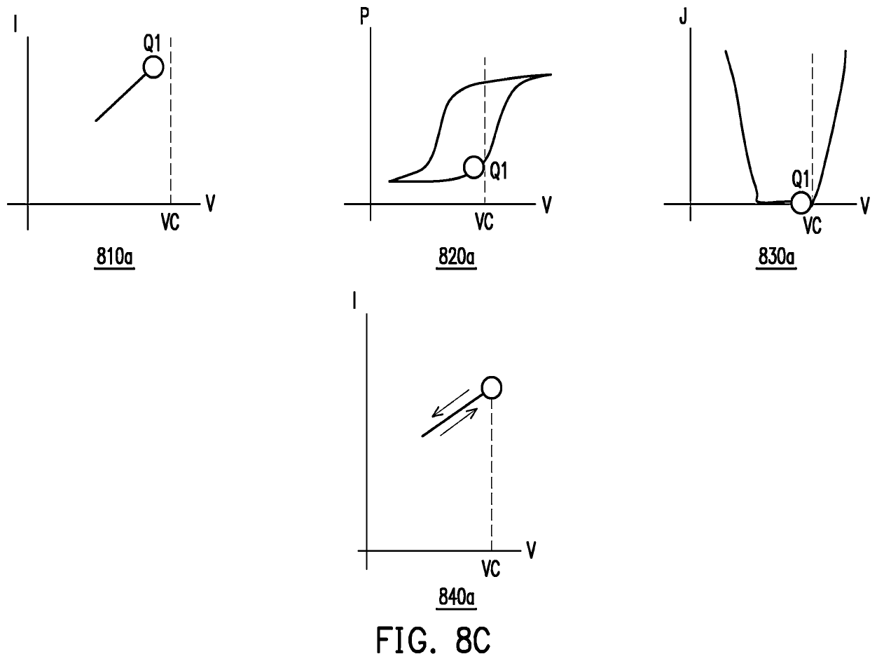

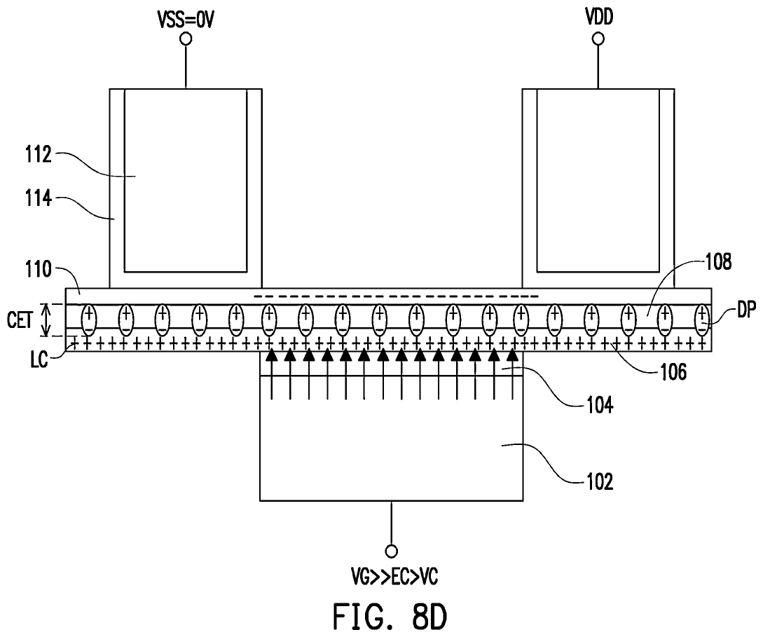

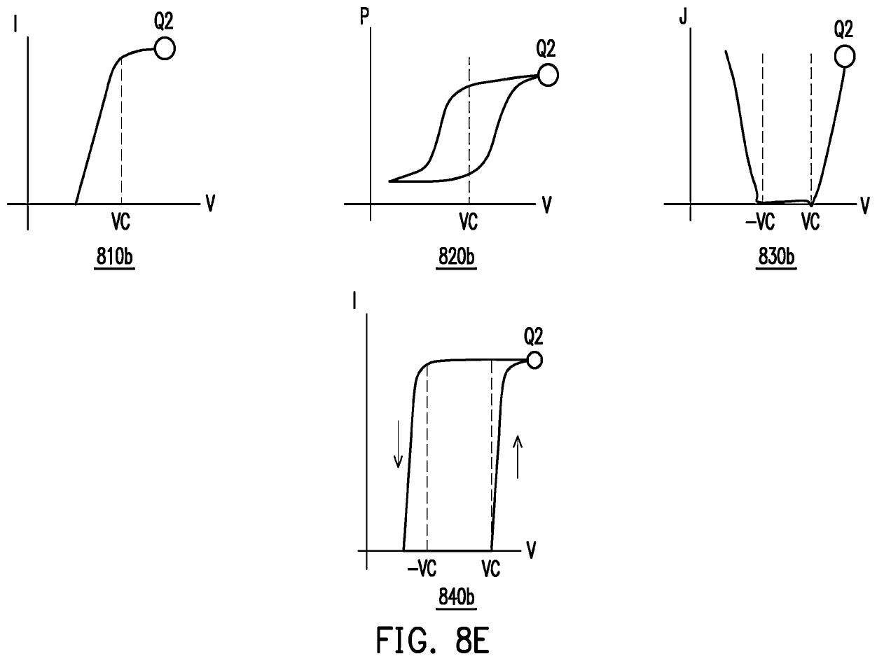

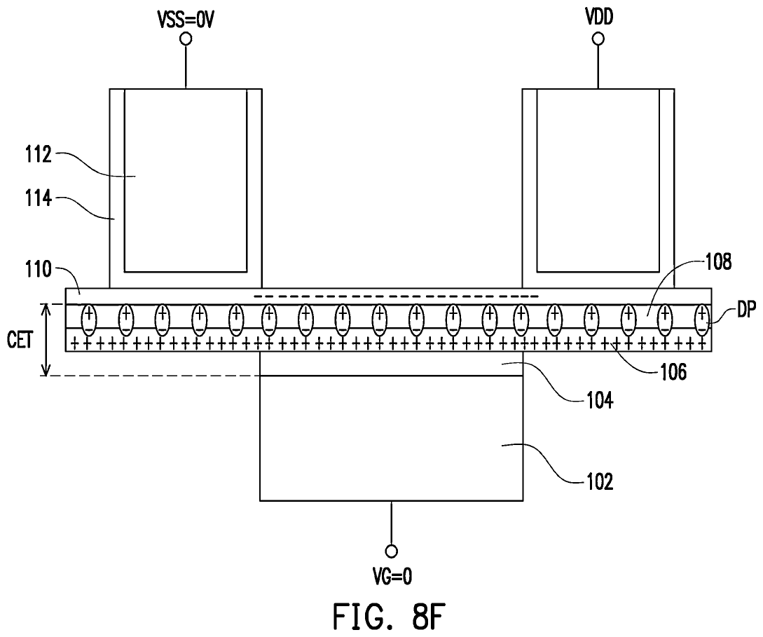

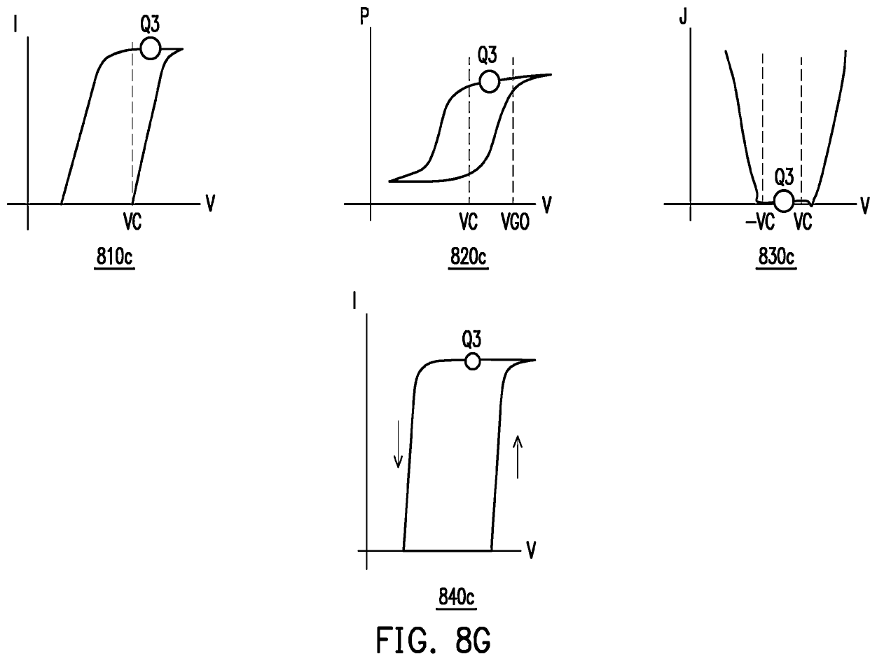

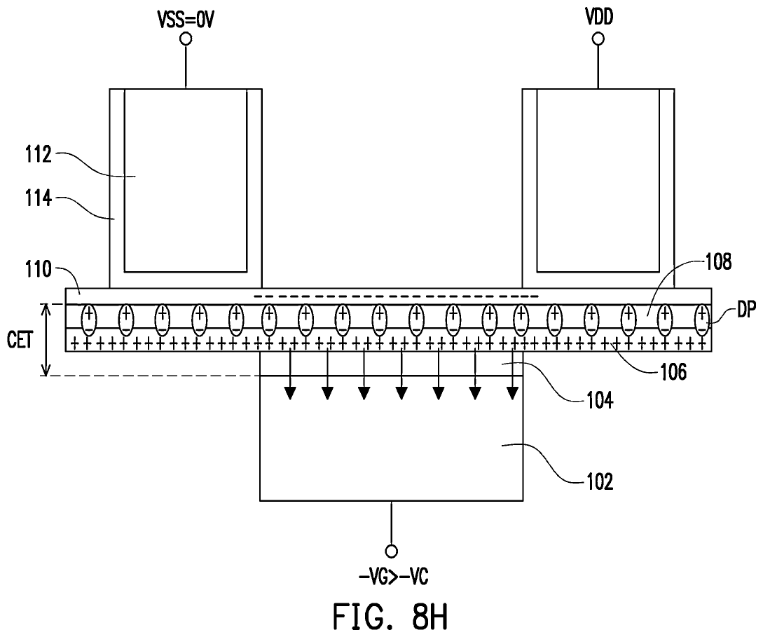

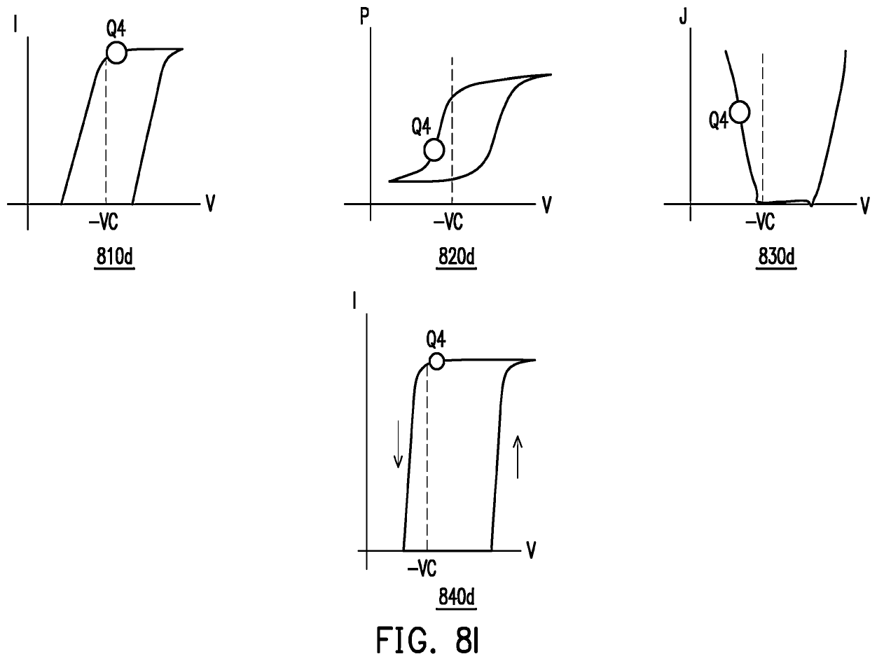

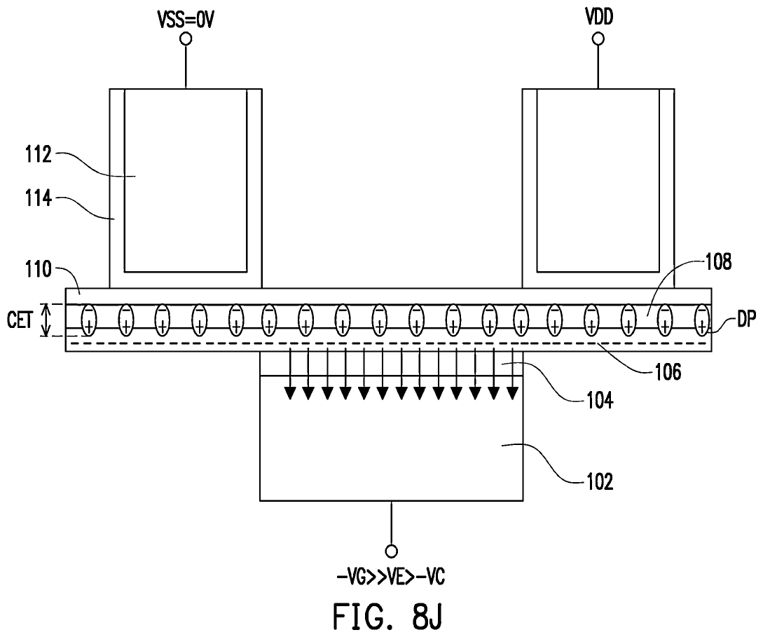

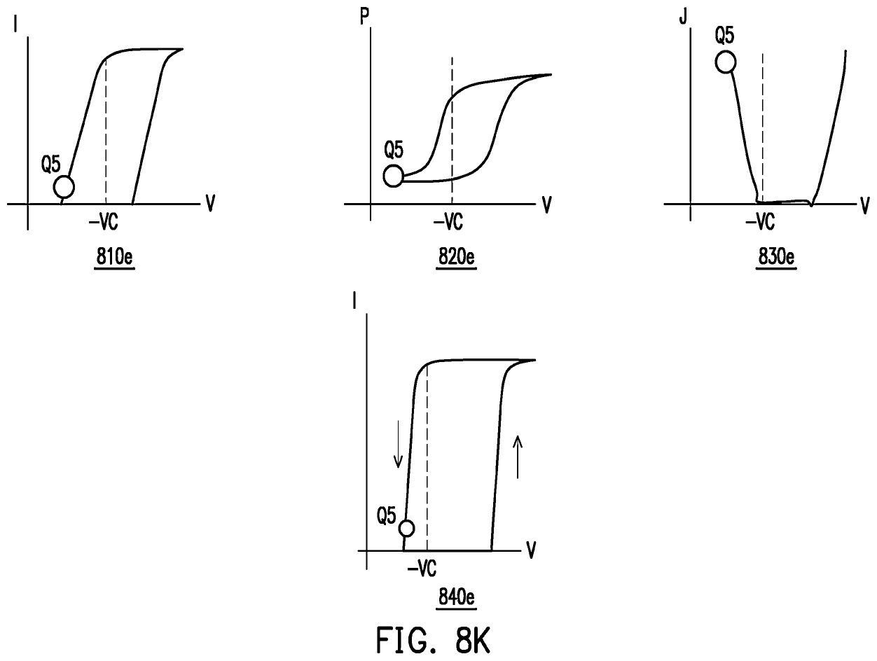

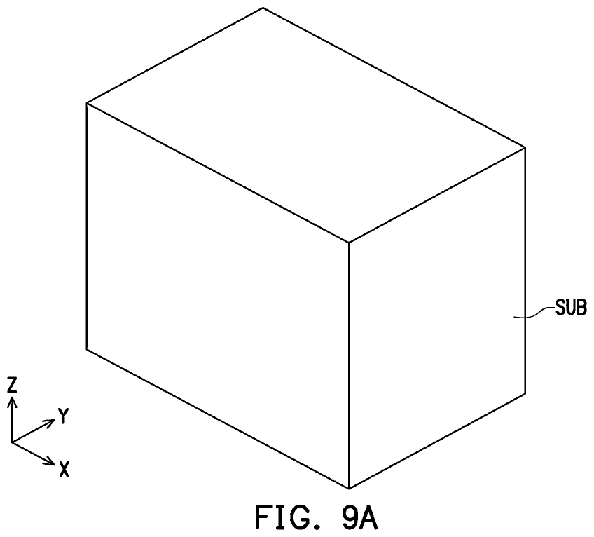

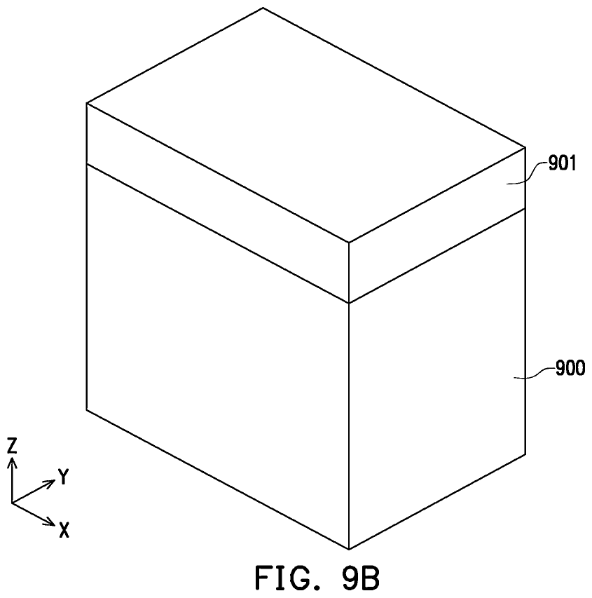

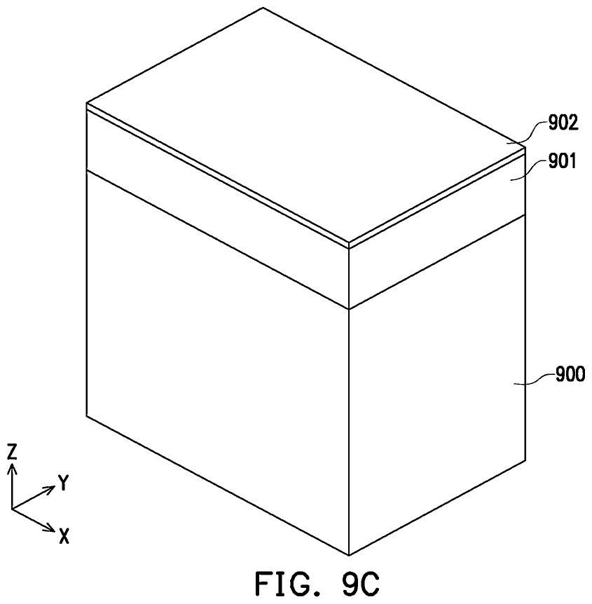

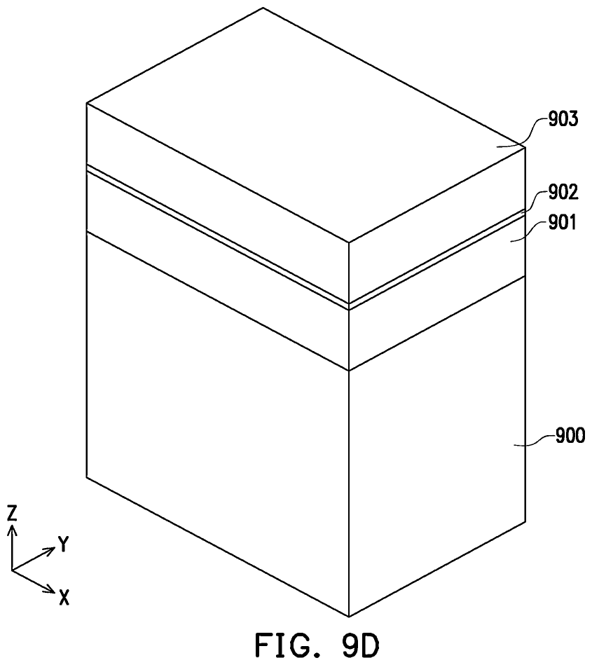

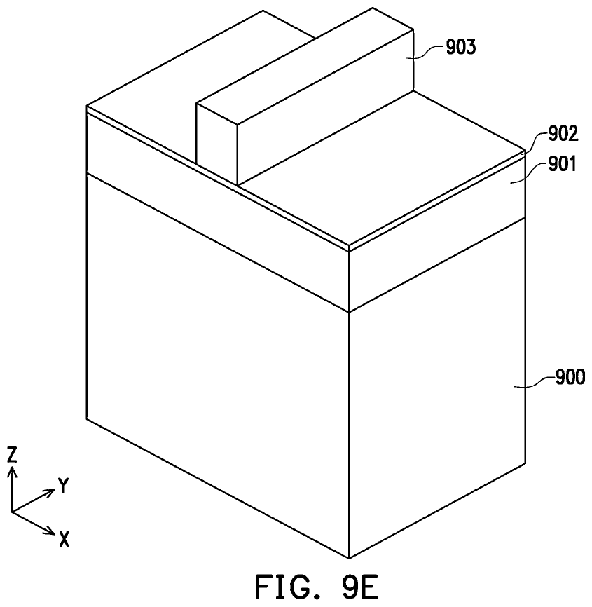

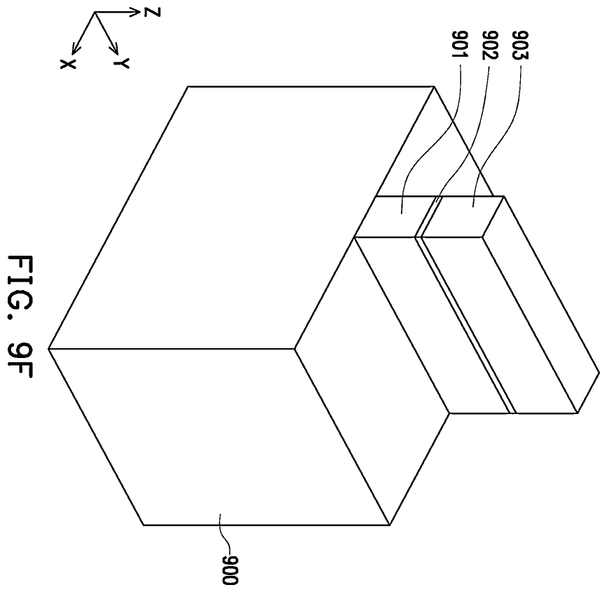

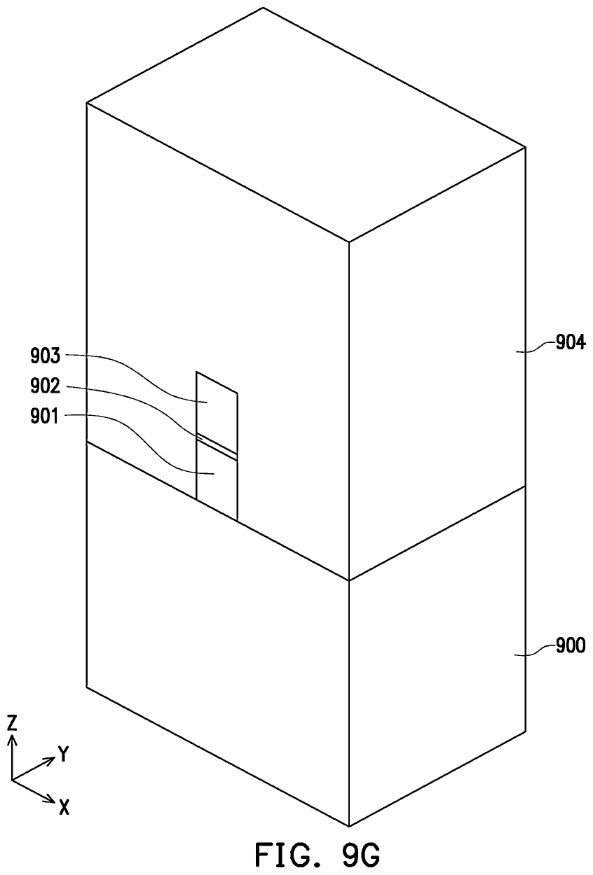

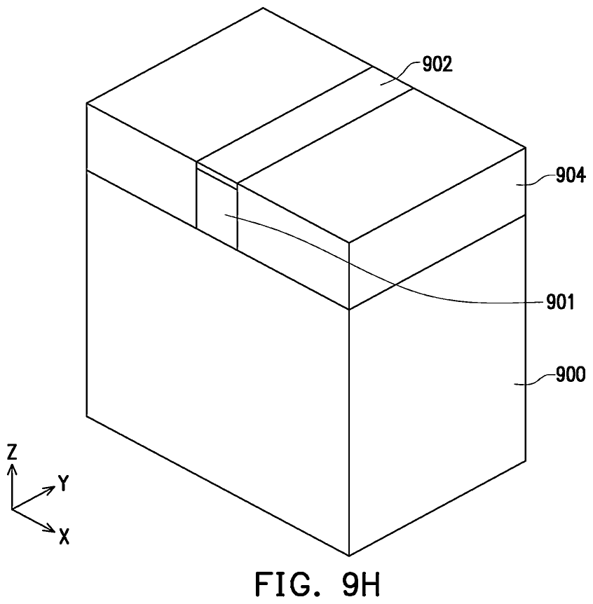

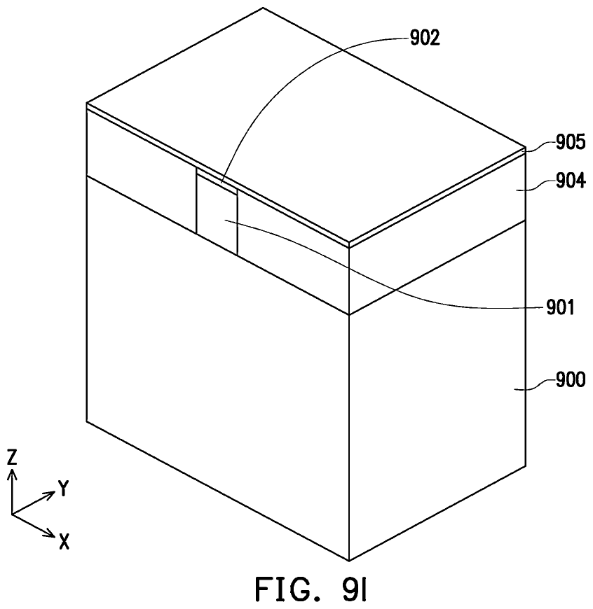

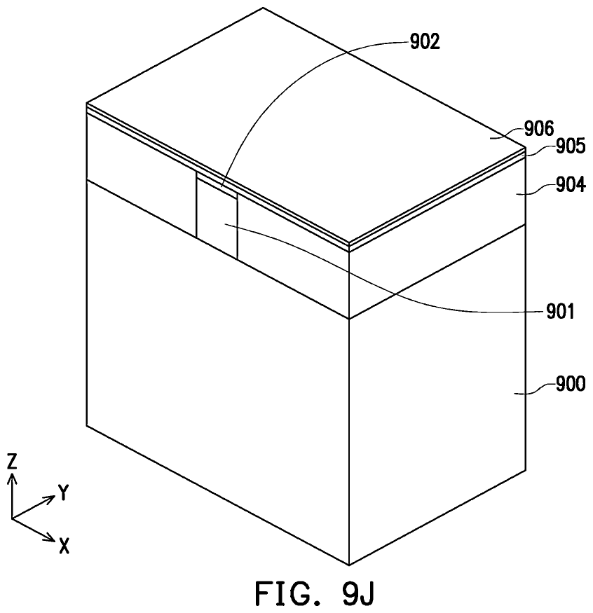

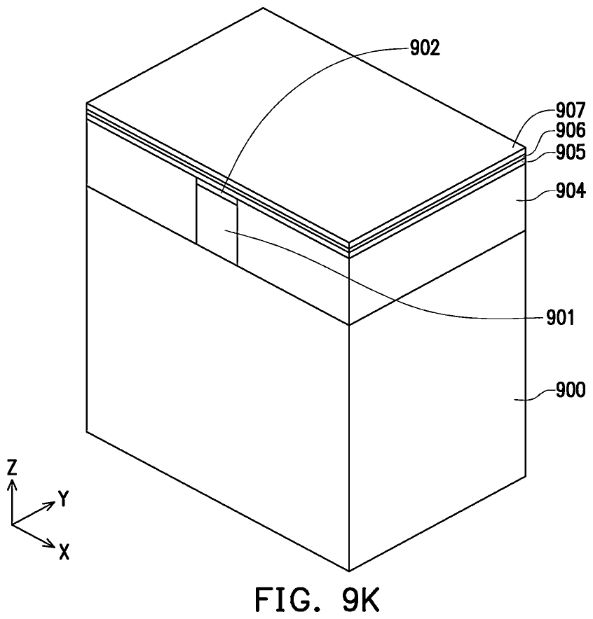

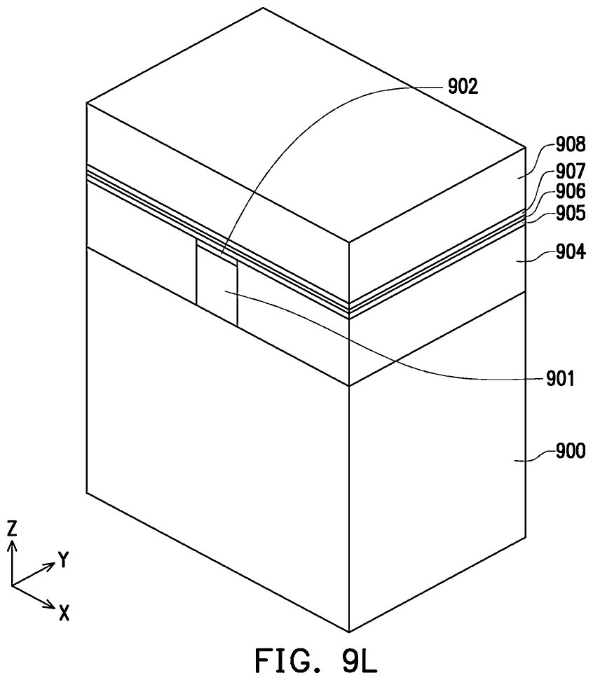

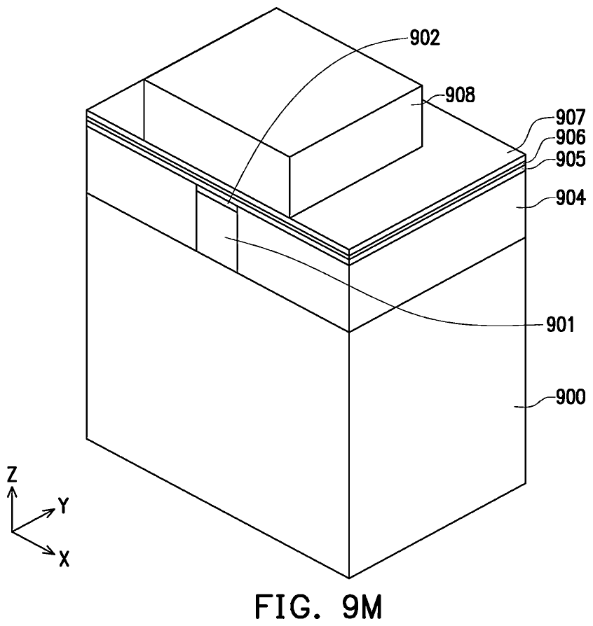

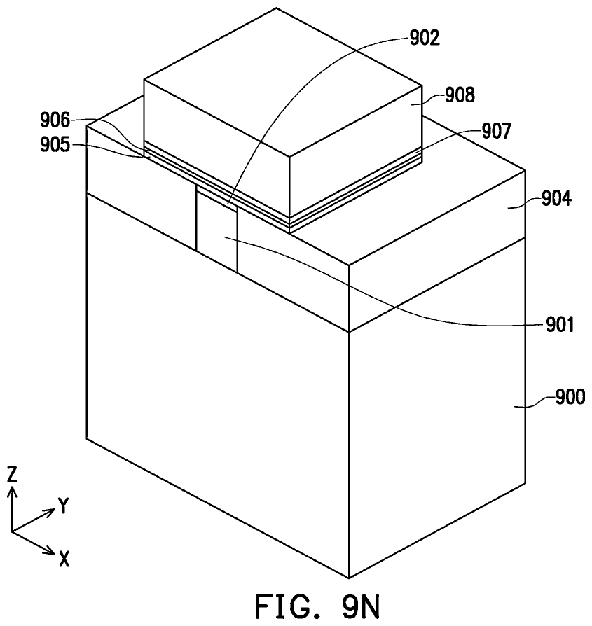

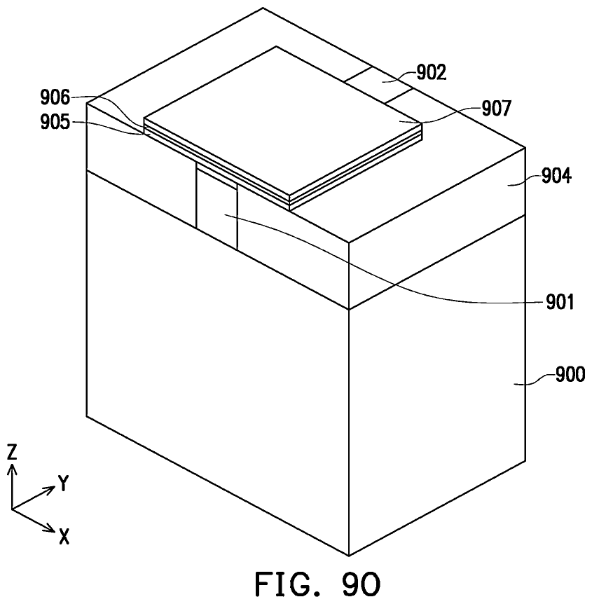

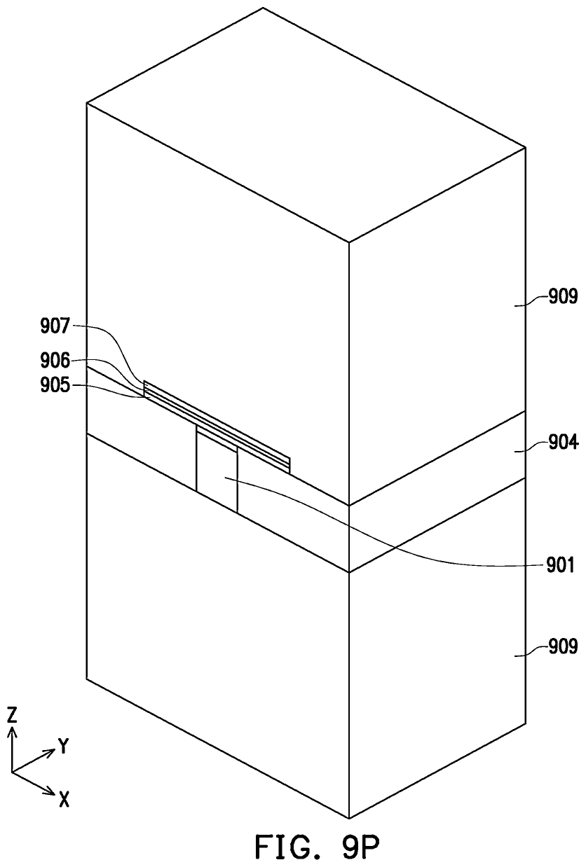

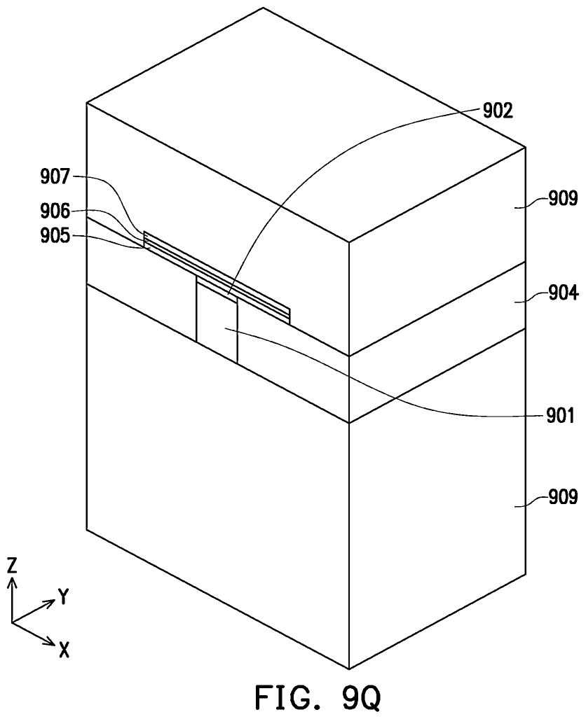

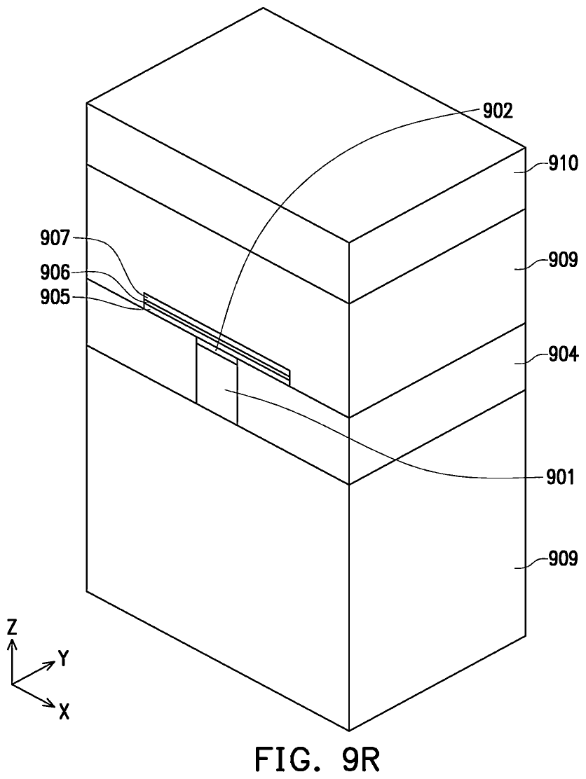

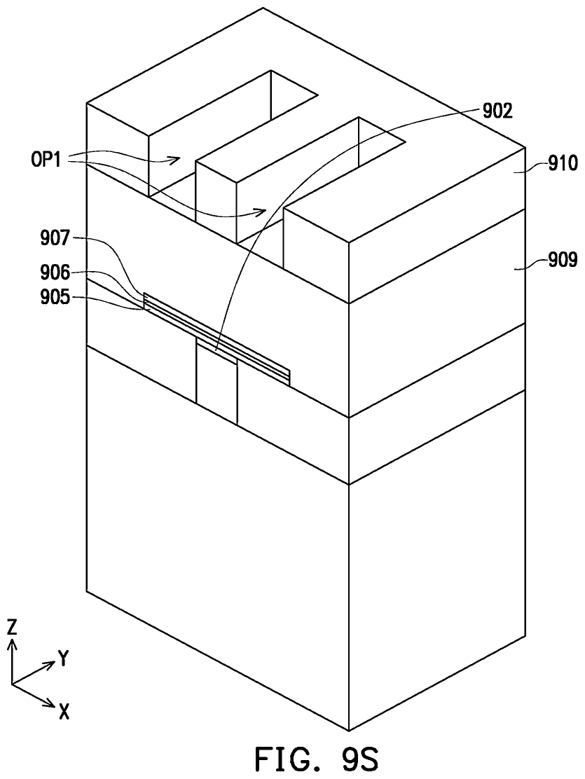

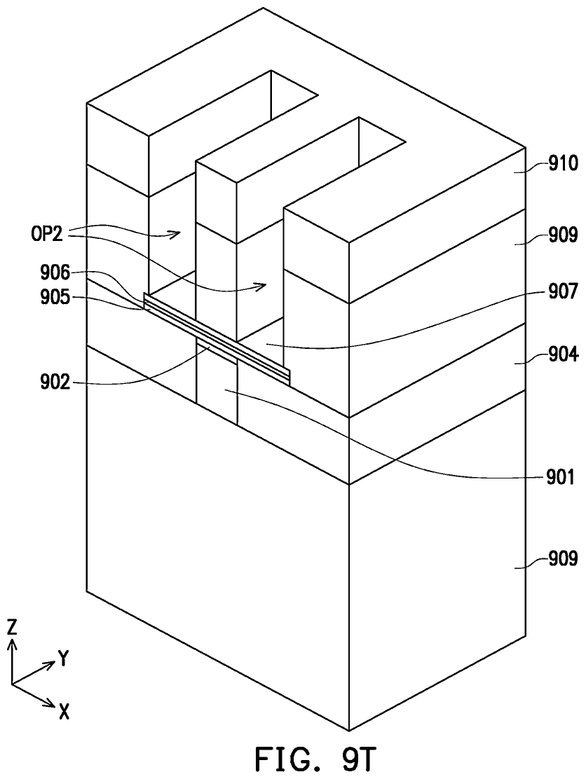

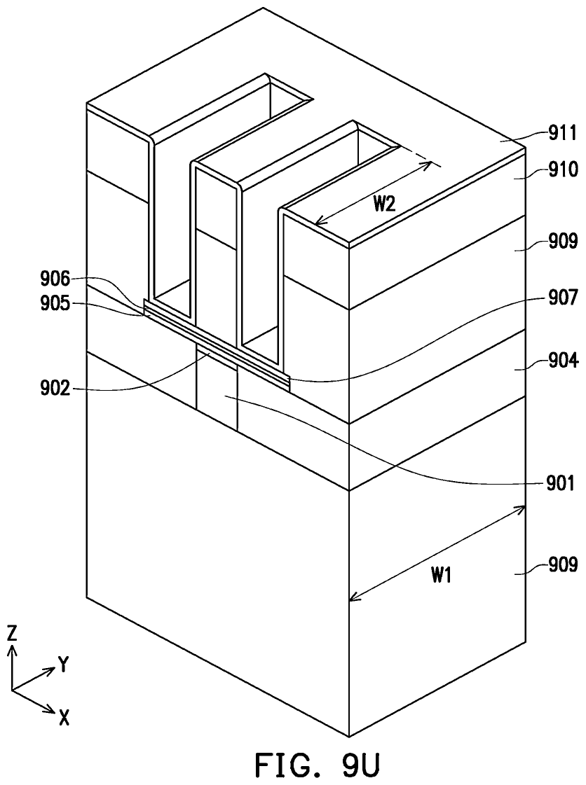

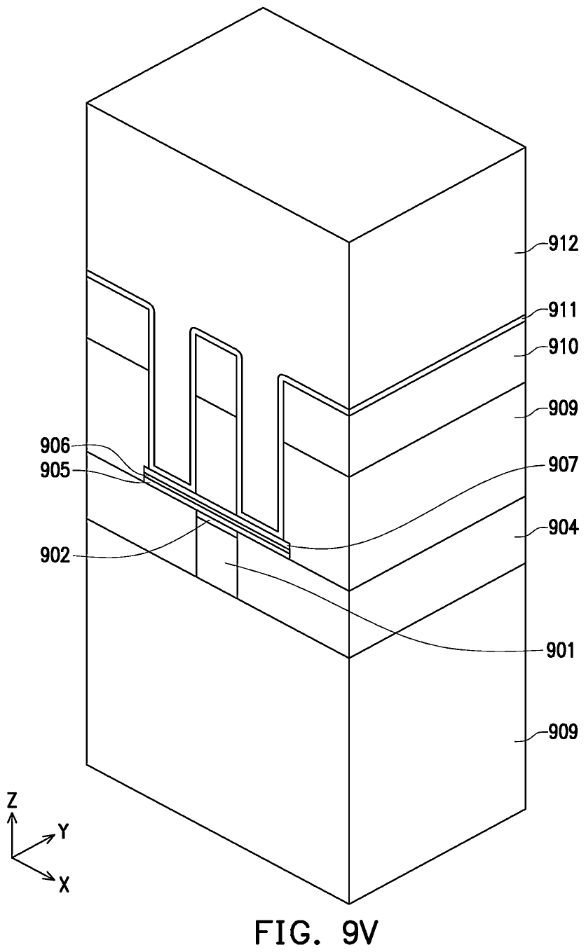

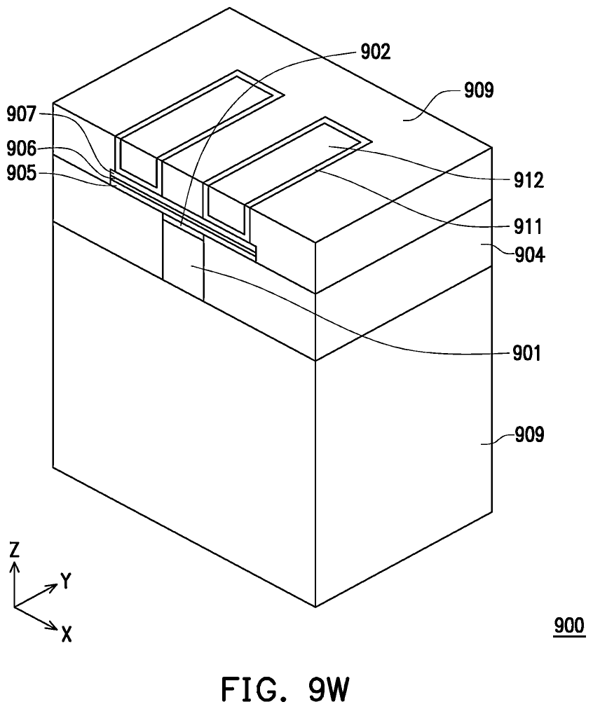

FIG. 1A and FIG. 1B respectively illustrate a schematic sectional view of a memory device and a top view of the memory device layout according to some embodiments of the present disclosure. FIG. 2A and FIG. 2B respectively illustrate a schematic sectional view of a memory device and a top view of the memory device layout according to some embodiments of the present disclosure. FIG. 3A and FIG. 3B respectively illustrate a schematic sectional view of a memory device and a top view of the memory device layout according to some embodiments of the present disclosure. FIG. 4A and FIG. 4B respectively illustrate a schematic sectional view of a memory device and a top view of the memory device layout according to some embodiments of the present disclosure. FIG. 5A and FIG. 5B respectively illustrate a schematic sectional view of a memory device and a top view of the memory device layout according to some embodiments of the present disclosure. FIG. 6 is a transmission electron microscope (TEM) picture of a sectional view of the memory device, in accordance with some embodiments. FIG. 7 is a current versus voltage curve (I-V) of the memory device, in accordance with some embodiments. FIG. 8A to FIG. 8K are I-V curves, polarization versus voltage (P-V) curves, and gate leakage current versus voltage (J-V) curves of the schematic sectional views of the memory device during various operation stages according to some embodiments of the present disclosure. FIG. 9A to FIG. 9W are schematic sectional views of various stages in a method of fabricating a memory device according to some embodiments of the present disclosure. Embodiments will be described with respect to a specific context, namely a semiconductor device, such as a ferroelectric field-effect transistor (Fe-FET) based memory device. Other embodiments may also be applied, however, to other circuits and layouts. Throughout the various views and illustrative embodiments, like reference numbers are used to designate like elements.

FIG. 1A is schematic sectional view of a memory device according to some embodiments of the present disclosure. FIG. 1B is a top view of the structure shown in FIG. 1A taken along a dash-line A-A′. It is to be noted that the process steps described herein cover a portion of the manufacturing processes used to fabricate the semiconductor device involving a semiconductor component such as a semiconductor memory device. The embodiments are intended to provide further explanations but are not used to limit the scope of the disclosure. In the disclosure, it should be appreciated that the illustration of components throughout all figures is schematic and is not in scale.

In some embodiments, the semiconductor device (not shown) is formed with embedded or integrated memory devices 100. In some embodiments, the semiconductor device includes field effect transistor (FET) devices formed through the front-end-of-line (FEOL) manufacturing processes and three-dimensional (3D) memory devices formed through the back-end-of-line (BEOL) manufacturing processes. In one embodiment, the FET devices include metal oxide semiconductor field effect transistors (MOSFETs), and the at least one of the memory devices 100 includes ferroelectric random access memory (FeRAM) devices. It is understood that MOSFETs are used as examples, and other kinds of FEOL devices such as planar transistors, thin film transistors, fin type FETs (FinFETs) or gate-all-around (GAA) transistors may be used herein and included within the scope of the present disclosure. That is, the memory devices 100 may be integrated with or in any suitable semiconductor devices. In FIGS. 1A and 1B, the details of the memory device 100 are shown and further details will be described later in subsequent figures.

The FET devices (not shown) are formed on the substrate, and isolation regions (not shown), such as shallow trench isolation (STI) regions, are formed between or around the FET devices. In some embodiments, the FET device includes a gate electrode are formed over the substrate with gate spacers formed along sidewalls of the gate electrode, and source/drain regions, such as doped regions or epitaxial source/drain regions, are formed on opposing sides of the gate electrode. In some embodiments, conductive contacts, such as gate contacts and source/drain contacts, are formed over and electrically coupled to respective underlying electrically conductive features (e.g., gate electrodes or source/drain regions). In some embodiments, a dielectric layer, such as an inter-layer dielectric (ILD) layer, is formed over the substrate and covering the source/drain regions, the gate electrode and the contacts, and other electrically conductive features, such as metallic interconnect structures comprising conductive vias and conductive lines, are embedded in the dielectric layer. It is understood that the dielectric layer may include more than one dielectric layers of the same or different dielectric materials. Collectively, the substrate, the FET devices, the contacts, conductive features, and the dielectric layers may be referred to as the front-end level.

Referring to FIG. 1A and FIG. 1B, a semiconductor memory device 100 is provided. The memory device 100 includes a gate structure, a ferroelectric structure 108 over and electrically connected with the gate structure, a channel structure 110 over the ferroelectric structure 108, and a plurality of contact structures 112 over the channel structure 110. The gate structure includes a first gate 102 as a back gate, a second gate 106 as a floating gate, and a tunneling layer 104 sandwiched there-between. The plurality of contact structures 112 are laterally spaced apart with each other by a predetermined distance L1. In some embodiments, the sidewalls SW1 of the first gate 102 are aligned with sidewalls SWC of the plurality of contact structures 112.

Referring to FIG. 1A and FIG. 1B, a dielectric layer 101 (or interlayer dielectric (ILD) layer) is provided. In some embodiments, the dielectric layer 101 is provided over a substrate (not shown) compatible with a back-end-of-line (BEOL) process of the semiconductor device.

In some embodiments, the substrate may be a bulk semiconductor substrate, such as a silicon substrate, doped or undoped, or an active layer of a semiconductor-on-insulator (SOI) substrate. In some embodiments, the substrate may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. For example, additional electrical components, such as resistors, capacitors, inductors, diodes, or the like, may be formed in or on the substrate during the FEOL manufacturing processes.

The dielectric layer 101 is for example made of dielectric materials such as silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some other embodiments, the dielectric layer 101 is made of low-K dielectric materials such as BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. It should be noted that the low-k dielectric materials are generally dielectric materials having a dielectric constant lower than 3.9. The dielectric layer 101 may be formed by any suitable method, such as chemical vapor deposition (CVD), spin-on, sputtering, or the like.

Referring to FIG. 1A and FIG. 1B, in a subsequent step, a gate structure is formed in the dielectric layer 101. The gate structure is a metal-insulator-metal structure and may be disposed over and/or on a substrate. The gate structure includes a back (or control) gate 102, a floating gate 106, and a tunneling layer 104 sandwiched between the back gate 102 and the floating gate 106. The back gate 102 is patterned to form a first gate 102 (or first gate electrode). In some embodiments, the first gate 102 includes a metal material such as W, Ti, TiN, TaN, TiAl, Mo, the like, or combinations thereof. Furthermore, the first gate 102 may be formed by suitable deposition techniques, or the like. After forming the first gate 102, a tunneling layer 104 is formed in the dielectric layer 101 to cover the first gate 102. In some embodiments, the length L1 of the first gate 102 is substantially the same as the length L1 of the tunneling layer 104. In some embodiments, the length L2 of the second gate 102 is substantially larger than the length L1 of the first gate 102 and the length L1 of the tunneling layer 104. After forming the first gate 102, the dielectric layer 101A may be formed by the same method and be formed of similar materials as described for the dielectric layer 101, thus its detailed description will be omitted herein. Subsequently, a planarization process (e.g., a chemical-mechanical planarization (CMP) process) is performed to remove excessive dielectric materials of the dielectric layer 101A so that a top surface of the first gate 102 is coplanar (or aligned) with a top surface of the dielectric layer 101A.

In some embodiments, the second gate (floating gate) 106 may be an oxide-nitride-oxide (ONO) structure, a first silicon oxide film is formed (not shown). The first silicon oxide film is a film for tunneling charges. The second silicon oxide film is formed out of any of SiO₂, Al₂O₃, Y₂O₃, etc. A nitride film (Si₃O₄) (not shown) is formed on the first silicon oxide film. The nitride film is a material film in which data is substantially stored, and charges tunneling the first silicon oxide film using the direct tunneling or F-N tunneling technique during the programming operation are trapped in the trap site. The second silicon oxide film (not shown) is formed on the nitride film as a blocking film for blocking the charge from moving upward through the nitride film. In some embodiments, the second silicon oxide film is formed out of any of HfO₂, ZrO₂, BaZrO₂, BaTiO₃, Ta₂O₅, CaO, SrO, BaO, La₂O₃, Ce₂O₃, Pr₂O₃, Nd₂O₃, Pm₂O₃, Sm₂O₃, Eu₂O₃, Gd₂O₃, Tb₂O₃, Dy₂O₃, Ho₂O₃, Er₂O₃, Tm₂O₃, Yb₂O₃, and/or Lu₂O₃.

Also, the electric potential barrier between the first silicon oxide film and the nitride film is higher than the electric potential barrier between the nitride film and the second silicon oxide film. As a result, electrons cannot jump over the high electric potential barrier, even in a hot or other environment; thereby resulting in an improvement of the retention characteristic.

The second gate (floating gate) 106 comprises a dielectric material optimized for storing of electrical charges. The floating gate 106 has an equivalent oxide thickness (EOT), which is herein referred to as a “floating gate dielectric EOT,” and optimized for storing of electrical charges. The floating gate 106 may comprise a dielectric material formed by thermal conversion of a portion of the semiconductor fin, such as silicon oxide or silicon nitride. Alternately, the floating gate 106 may comprise a high-k dielectric material having a dielectric constant greater than 3.9, i.e., the dielectric constant of silicon oxide. Exemplary high-k dielectric materials include HfO₂, ZrO₂, La₂O₃, Al₂O₃, TiO₂, SrTiO₃, LaAlO₃, Y₂O₃, an alloy thereof, and a silicate thereof. The high-k dielectric material may be formed by methods well known in the art including, for example, a chemical vapor deposition (CVD), a physical vapor deposition (PVD), an atomic layer deposition (ALD), molecular beam epitaxy (MBE), pulsed laser deposition (PLD), liquid source misted chemical deposition (LSMCD), etc.

In some embodiment, the tunneling layer 104 includes one or more oxide materials such as HfO₂, ZrO₂, BaZrO₂, BaTiO₃, Ta₂O₅, CaO, SrO, BaO, La₂O₃, Ce₂O₃, Pr₂O₃, Nd₂O₃, Pm₂O₃, Sm₂O₃, Eu₂O₃, Gd₂O₃, Tb₂O₃, Dy₂O₃, Ho₂O₃, Er₂O₃, Tm₂O₃, Yb₂O₃, and/or Lu₂O₃.

After forming the tunneling layer 104, a second gate 106 is formed in the dielectric layer 101B to cover the tunneling layer 104. In the exemplary embodiment, the second gate 106 include high-k dielectric materials such as aluminum oxide (Al₂O₃), hafnium oxide (HfO₂), hafnium lanthanum oxide (HfLaO), or the like. The first gate dielectric 106 may be formed by any suitable method, such as chemical vapor deposition (CVD), or the like.

After forming the gate structure, a ferroelectric structure 108 (or an insulating layer/ferroelectric insulating layer) is formed in the dielectric layer 101B to cover the second gate 106. After forming the ferroelectric structure 108, a channel structure 110 is formed in the dielectric layer 101B to cover the ferroelectric structure 108 along a first direction (build-up direction or z-direction). For example, the second gate 106 is disposed on the dielectric layer 101A in between the tunneling layer 104 and the ferroelectric structure 108. Furthermore, the ferroelectric layer 108 is surrounded by the dielectric layer 101B in between the second gate 106 and the channel structure 110. The dielectric layer 101B may be formed by the same method and be formed of similar materials as described for the dielectric layer 101, 101A, thus its detailed description will be omitted herein. Subsequently, a planarization process (e.g., a chemical-mechanical planarization (CMP) process) is performed to remove excessive dielectric materials of the dielectric layer 101B so that a top surface of the channel structure 110 is coplanar (or aligned) with a top surface of the dielectric layer 101B.

In some embodiment, the ferroelectric structure 108 (or insulating layer/ferroelectric insulating layer) comprises a ferroelectric material selected from the group consisting of silicon doped hafnium oxide (Si:HfO₂), hafnium zirconium oxide (HfZrO₂), aluminum scandium nitride (AlScN) and aluminum yttrium nitride (AlYN). For example, when the first semiconductor layer (or first channel layer) and the second semiconductor layer (or second channel layer) are made of oxide semiconductor materials, then the ferroelectric structure 108 (or insulating layer/ferroelectric insulating layer) is a high-k material such as silicon doped hafnium oxide (Si:HfO₂) or hafnium zirconium oxide (HfZrO₂). In certain embodiments, when the first semiconductor layer (or first channel layer) and the second semiconductor layer (or second channel layer) are made of III-N semiconductor materials, then the ferroelectric structure 108 (or insulating layer/ferroelectric insulating layer) is aluminum scandium nitride (AlScN) or aluminum yttrium nitride (AlYN). In one embodiment, aluminum scandium nitride (AlScN) can be monolithically deposited/formed (i.e. in a single-crystalline manner) on the first semiconductor layer as the ferroelectric structure 108. In addition, the ferroelectric structure 108 may be formed through suitable deposition techniques, such as atomic layer deposition (ALD), chemical vapor deposition (CVD), metal organic chemical vapor deposition (MOCVD), plasma enhanced chemical vapor deposition (PECVD), sputtering or the like.

In some embodiments, the channel structure 110 (or channel layer) in contact with the side wall structures 114 is made of oxide semiconductor materials such as indium-gallium-zinc oxide (InGaZnO or IGZO), gallium oxide (Ga₂O₃), indium oxide (In₂O₃), zinc oxide (ZnO), indium tin oxide (ITO), or the like. In some alternative embodiments, the channel structure 110 is made of III-N semiconductor materials such as gallium nitride (GaN), indium nitride (InN), indium gallium nitride (InGaN), or the like. In some alternative embodiments, the channel structure 110 is made of group-IV semiconductor materials such as silicon (Si), germanium (Ge), silicon germanium (SiGe), or the like. In some alternative embodiments, the channel structure 110 may be formed by the first semiconductor layer (or first channel layer) and the second semiconductor layer (or second channel layer) (not shown). The first semiconductor layer (or first channel layer) and the second semiconductor layer (or second channel layer) may be formed of the same material or be formed of different materials, and may be formed by any suitable method, such as atomic layer deposition (ALD), chemical vapor deposition (CVD), metal organic chemical vapor deposition (MOCVD), plasma enhanced chemical vapor deposition (PECVD), sputtering or the like. Furthermore, the first semiconductor layer and the second semiconductor layer may be single crystalline, poly crystalline, or amorphous.

In some embodiments, the length L2 of the second gate is the same as the length L2 of the ferroelectric structure 108 and the length L2 of the channel structure 110.

In some embodiments, after forming the channel structure 110, in a next step, portions of the dielectric layer 101C are further removed by patterning or etching processes. For example, the dielectric layer 101C are patterned to reveal portions of the plurality of the contact structures 112 located on the channel structure 110. For another example, the dielectric layer 101C are patterned to form portions of the plurality of the contact structures 112 surrounded by the dielectric layer 101C and located on the channel structure 110. In detail, in a subsequent step, the openings in the dielectric layer 101C are filled with conductive materials to form contact structures 112 connected to the channel structure 110. For example, the conductive materials include copper, aluminum, tungsten, titanium nitride (TiN), tantalum nitride (TaN), some other conductive materials, or any combinations thereof. In some embodiments, the contact structure includes source and drain contacts (not shown). After forming the contact structures 112, a semiconductor device 100 according to some embodiments of the present disclosure is accomplished. In some embodiments, the second gate 106, the ferroelectric structure 108 and the channel structure 110 are patterned together so that sidewalls of the ferroelectric structure 108 are aligned with sidewalls of the channel structure 110 and the second gate 106.

Referring to FIG. 1A and FIG. 1B, the first gate 102 and the tunneling layer 104 has the same width W1 taken along the y-direction in the layout of the memory device 100. In some embodiments, the second gate 106, the ferroelectric structure 108, and the channel structure 110 has the same width W2 taken along the y-direction in the layout of the memory device 100. In some embodiments, each contact structures 112 has the width W3 taken along the y-direction in the layout of the memory device 100. In some embodiments, the width W1 of the tunneling layer 104 is larger than the width W2 of the channel structure 110. The width W2 of the channel structure 110 is larger than the width W3 of each contact structures 112. In some embodiments, the width W1 of the tunneling layer 104 is substantially the same as the width W2 of the channel structure 110.

Referring to FIG. 1A, FIG. 1B, FIG. 6, and FIG. 7, it should be noted that the tunneling layer 104 is not in contact with the channel structure 110 and is surrounded by the first gate 102 and the second gate 106, leading counter-clockwise hysteresis in the current versus voltage (I-V) curve of the memory device 100. In addition, the two branches (up and down) show nearly ideal sub-threshold slope (S) (i.e., S=70 mV/dec), wherein the sub-threshold slope (S) of the up branch is nearly 73 mV/dec and the sub-threshold slope of the down branch is nearly 68 mV/dec. Moreover, the memory window of the memory device 100 is about 2 V.

In the semiconductor device 100 of the exemplary embodiment, the ferroelectric structure 108 is shared between two transistors at two opposite sides to form a differential pair structure design. As such, when one transistor writes the polarization in one of the two stable states, the other transistor will always be in the complementary state. Therefore, the writing of such semiconductor device 100 can be completed in one operation, and reading can be done differentially, like in static random-access memory (SRAM).

FIG. 2A is schematic sectional view of a memory device according to some embodiments of the present disclosure. FIG. 2B is a top view of the structure shown in FIG. 2A taken along the line A-A′. Referring to FIG. 2A and FIG. 2B,

Referring to FIG. 2A and FIG. 2B, the memory device 200 is provided. Therefore, the same reference numerals are used to refer to the same or liked parts, and its detailed description will be omitted herein. In some embodiments, each contact structures 112 includes a sidewall structure 114 covering the bottom and two lateral sides of each contact structures. In some embodiments, the material of the sidewall structure 114 includes semiconductor oxide and in contact with the channel structure 110.

In some embodiments, the length L4 of the sidewall structure 114 is larger than the length L3 of the contact structures 112. In some embodiments, the width W4 of the sidewall structure 114 is larger than the width W3 of the contact structures 112. In some embodiments, the width W4 of the sidewall structure 114 is smaller than the width W2 of the channel structure 110. In some embodiments, the width W5 of part of the tunneling layer 104 is smaller than the width W6 of part of the tunneling layer 104. In alternative embodiments, the width W5 of part of the tunneling layer 104 is the same as the width W6 of part of the tunneling layer 104.

In some embodiments, the first gate 102 and the tunneling layer 104 is a selector-like gate 120. The first gate 102, the tunneling layer 104, and the second gate 106 acts as s metal-insulator-metal (MIM) selector 130. The second gate 106, the ferroelectric structure 108, and the channel structure 110 is a metal-ferroelectric-semiconductor (MFS) capacitor 140. The MFS capacitor 140, the sidewall structure 114, and the contact structures 112 is an IGZO Fe-FET 150. That is, the memory device 200 is operated by these devices (i.e., the selector-like gate 120, the MFS capacitor 140, and the IGZO FE-FET 150) working simultaneously in series.

FIG. 3A is schematic sectional view of a memory device according to some embodiments of the present disclosure. FIG. 3B is a top view of the structure shown in FIG. 3A taken along the line A-A′.

Referring to FIG. 3A and FIG. 3B, the memory device 300 is provided. Therefore, the same reference numerals are used to refer to the same or liked parts, and its detailed description will be omitted herein. In some embodiments, each contact structures 112 includes a sidewall structure 114 covering the bottom and two lateral sides of each contact structures. In some embodiments, the material of the sidewall structure 114 includes semiconductor oxide and in contact with the channel structure 110.

In some embodiments, the first gate 102, the tunneling layer 104, and the second gate 106 has the same length L1 as the predetermined length L1 of the separated distance between each sidewall structures 114 of the contact structures 112. In some embodiments, the ferroelectric structure 108 and the channel structure 110 has the same length L2, wherein the length L2 is larger than the length L1. In some embodiments, the width W4 of the sidewall structure 114 is larger than the width W3 of the contact structures 112. In some embodiments, the width W4 of the sidewall structure 114 is smaller than the width W2 of the channel structure 110. In some embodiments, the width W5 of part of the second gate 106 is smaller than the width W6 of part of the second gate 106. In alternative embodiments, the width W5 of part of the second gate 106 is the same as the width W6 of part of the second gate 106.

FIG. 4A is schematic sectional view of a memory device according to some embodiments of the present disclosure. FIG. 4B is a top view of the structure shown in FIG. 1A taken along the line A-A′.

Referring to FIG. 4A and FIG. 4B, the memory device 400 is provided. Therefore, the same reference numerals are used to refer to the same or liked parts, and its detailed description will be omitted herein. In some embodiments, each contact structures 112 includes a sidewall structure 114 covering the bottom and two lateral sides of each contact structures. In some embodiments, the material of the sidewall structure 114 includes semiconductor oxide and in contact with the channel structure 110.

In the exemplary embodiment, the first gate 102, the tunneling layer 104, the second gate 106, the ferroelectric structure 108, and the channel structure 110 may be sequentially formed over the substrate and under the dielectric layers 101 (part of the interlayer dielectric layer). For example, the first gate 102, the tunneling layer 104, the second gate 106, the ferroelectric structure 108, and the channel structure 110 are patterned together so that sidewalls of first gate 102, the tunneling layer 104, the second gate 106, the ferroelectric structure 108, and the channel structure 110 are aligned with each other. In some embodiments, the first gate 102, the tunneling layer 104, the second gate 106, the ferroelectric structure 108, and the channel structure 110 has the same length L2′ along the x-direction. In some embodiments, the separated distance L1′ between each sidewall 114 of the contact structures 112 shown in FIG. 4B is smaller than the length L2′ of the second gate 106. In some embodiments, the length L2′ of the second gate 106 is the same as the length L2′ of the channel structure 110. In some embodiments, the length L4 of the sidewall structure 114 is larger than the length L3 of the contact structures 112. In some embodiments, the width W4 of the sidewall structure 114 is larger than the width W3 of the contact structures 112. In some embodiments, the width W4 of the sidewall structure 114 is smaller than the width W2 of the channel structure 110. In some embodiments, the width W5 of part of the tunneling layer 104 is smaller than the width W6 of part of the tunneling layer 104. In alternative embodiments, the width W5 of part of the tunneling layer 104 is the same as the width W6 of part of the tunneling layer 104.

FIG. 5A is schematic sectional view of a memory device according to some embodiments of the present disclosure. FIG. 5B is a top view of the structure shown in FIG. 1A taken along the line A-A′.

Referring to FIG. 5A and FIG. 5B, the memory device 500 is provided. Therefore, the same reference numerals are used to refer to the same or liked parts, and its detailed description will be omitted herein. In some embodiments, each contact structures 112 may include a sidewall structure (not shown) covering the top and two lateral sides of each contact structures. In some embodiments, the material of the sidewall structure 114 includes semiconductor oxide and in contact with the channel structure 110.

In the exemplary embodiment, the contact structures 112 is formed in the dielectric layer 101. After forming the contact structures 112, subsequently, a planarization process (e.g., a chemical-mechanical planarization (CMP) process) is performed to remove excessive dielectric materials of the dielectric layer 101 so that a top surface of the contact structure 112 is coplanar (or aligned) with a top surface of the dielectric layer 101. After forming CMP process, the channel structure 110 is formed to cover the dielectric layer 101 and the contact structures 112. In some embodiments, after forming the channel structure 110, the ferroelectric structure 108, the second gate 106, the tunneling layer 104, and the first gate 102′ may be sequentially formed over the channel structure 110. For example, the first gate 102′, the tunneling layer 104, the second gate 106, and the ferroelectric structure 108 are patterned together so that sidewalls of first gate 102′, the tunneling layer 104, the second gate 106, and the ferroelectric structure 108 are aligned with each other. In some embodiments, the ferroelectric structure 108, the second gate 106, the tunneling layer 104, and the first gate 102′ have the same length L1. In some embodiments, at least one sidewall SW3 of the contact structures 112 is aligned with the sidewall SW4 of the channel structure 110. In some embodiments, at least one sidewall SW5 of the contact structures 112 is aligned with the sidewall SW6 of the ferroelectric structure 108, the tunneling layer 104, the second gate 106, and the first gate 102′. The height H1 along the z-direction of the first gate 102′ is larger than the height H2 along the z-direction of the tunneling layer 104. In some embodiments, the width W4 of the sidewall structure 114 is larger than the width W3 of the contact structures 112. In some embodiments, the width W4 of the sidewall structure 114 is smaller than the width W2 of the channel structure 110. In some embodiments, the width W5 of part of the tunneling layer 104 is smaller than the width W6 of part of the tunneling layer 104. In alternative embodiments, the width W5 of part of the tunneling layer 104 is the same as the width W6 of part of the tunneling layer 104. In some embodiments, the first gate 102′ is the top layer in the layout.

FIG. 6 is a transmission electron microscope (TEM) picture of a sectional view of the memory device, in accordance with some embodiments. Referring to FIG. 6, the memory device 600 is provided. The memory device 600 includes the first gate 102, the tunneling layer 104, the second gate 106, the ferroelectric structure 108, the channel structure 110, and the plurality of the contact structures 112.

FIG. 7 is a current versus voltage curve (I-V) of the memory device, in accordance with some embodiments. Referring to FIG. 7, a counter-clockwise hysteresis in the current (A/μm) versus voltage VGS (I-V) curve of the memory device is provided. The sub-threshold slope (S) of the up branch is nearly 73 mV/dec and the sub-threshold slope of the down branch is nearly 68 mV/dec. Moreover, the memory window of the memory device 100 is about 2 V.

FIG. 8A to FIG. 8K are I-V curve, polarization versus voltage (P-V) curve, and gate leakage current versus voltage (J-V) curve of the schematic sectional views of the memory device during various operation stages according to some embodiments of the present disclosure.

Referring to FIG. 8A and FIG. 2A, the I-V curve 810 of the IGZO FE-FET 150, the P-V curve 820 of the MFS capacitor 140, and the J-V curve 830 of the MIM selector 130 is provided. The critical voltage VC equals to the gate voltage at which the MIM selector 130 starts to leak.

Referring to FIG. 8B and FIG. 8C, the gate voltage VG is below the critical voltage VC, the source voltage VSS applied to one of the contact structures 112 is 0 V, and the drain voltage VDD applied to another contact structure 112 is at a predetermined voltage (or logic high). In this condition, there is no current passes the tunnel layer 104 yet. As a result, the ferroelectric structure 108/the second gate 106/the tunneling layer 104 acts as one gate dielectric having a relatively large capacitance-equivalent thickness CET ranging from the top surface of the ferroelectric structure 108 to the bottom surface of the tunneling layer 104 and high coulomb scattering because of random dipole DP orientation in the ferroelectric structure 108. Therefore, in this condition, higher coulomb scattering leads to poor gate modulation of the memory device. Also, there is a weak field, which is below the coercive field, over ferroelectric structure 108. Therefore, there is no ferroelectric structure 108 switching. The operation points Q1 are shown in the I-V curve 810a of the IGZO FE-FET 150, the P-V curve 820a of the MFS capacitor 140, the J-V curve 830a of the MIM selector 130, and the I-V curve 840a of the memory device. The I-V curve 840a of the memory device measurement method was applied to determine the hysteresis switching current characteristics of ferroelectric capacitors to obtain the P-V curve 820a loops. The CET is used to reflect the distance of the charge centroid from the oxide-semiconductor interface.

Referring to FIG. 8D and FIG. 8E, the gate voltage VG is above the critical voltage VC, the source voltage VSS applied to one of the contact structures 112 is 0 V, and the drain voltage VDD applied to another contact structure 112 is at a predetermined voltage (or logic high). In some embodiments, the gate voltage VG is relatively higher than the coercive field EC induced by the electrical field and the coercive field EC is higher than the critical voltage VC. In this condition, the MIM selector 130 starts to leak the charges LC from the ferroelectric structure 108. In consequence, only ferroelectric structure 108 acts as dielectric, leading better I-V characteristics. In addition, the gate voltage VG passes coercive field EC of the ferroelectric structure 108, thus contributes to nearly 100% polarization. The CET ranges from the top surface of the channel structure 110 to the bottom surface of the channel structure 110. The operation points Q2 are shown in the I-V curve 810b of the IGZO FE-FET 150, the P-V curve 820b of the MFS capacitor 140, the J-V curve 830b of the MIM selector 130, and the I-V curve 840b of the memory device.

In exemplary embodiments, the ferroelectric structure 108 may have a “up” polarization state or a “down” polarization state depending on the immobile sheet charges located at the interfaces of the ferroelectric structure 108. For example, during “up” polarization, the channel structure 108 has negative sheet charge at the interface of the ferroelectric structure 108, and has positive sheet charge at the interface of the first gate 102. In other words, the negative sheet charge at the channel structure 108 repels electrons, which increases the threshold voltage. On the other hand, the positive sheet charge at the first gate 102 attracts electrons, which decreases the threshold voltage. As such, the two conditions of the semiconductor memory device will have two threshold voltages.

Referring to FIG. 8F, FIG. 8G and FIG. 2A, the gate voltage VG drops back to zero voltage (i.e, the gate voltage VG is equal to 0 volt or |VG|=0 V), the source voltage VSS applied to one of the contact structures 112 is 0 V, and the drain voltage VDD applied to another contact structure 112 is at a predetermined voltage (or logic high). In some embodiments, when the gate turn-on voltage VG is larger than the gate voltage VG, and the gate voltage VG is larger than the critical voltage VC, the gate voltage VG drops, however, the charge is still retained by ferro dipole DP in the ferroelectric structure 108. As a result, the current does not follow upward I-V curve of the memory device. In some embodiments, when the gate voltage VG is smaller than the critical voltage VC, the MIM selector 130 closes and the second gate 106 acts as an MFS (or MIM) capacitor 140 to store charges and to shield the gate voltage VG modulation. As a result, it hardly impacts the current, nor does it have an impact on the switching in ferroelectric structure 108. There is not much happening with the current, and the transistor remains open. In addition, the CET ranging from the top surface of the ferroelectric structure 108 to the bottom surface of the tunneling layer 104 enlarges again though, reducing modulation. The operation points Q3 are shown in the I-V curve 810c of the IGZO FE-FET 150, the P-V curve 820c of the MFS capacitor 140, the J-V curve 830c of the MIM selector 130, and the I-V curve 840c of the memory device.

Referring to FIG. 8H, FIG. 8I and FIG. 2A, the absolute value of the gate voltage VG is smaller than 0 V and the absolute value of the gate voltage VG is larger than the absolute value of critical voltage VC (i.e, |VC|<|VG|<0 V), the source voltage VSS applied to one of the contact structures 112 is 0 V, and the drain voltage VDD applied to another contact structure 112 is at a predetermined voltage (or logic high). In this condition, the MIM selector 130 starts to discharge to the first gate 102, and the gate voltage VG modulation is getting better again. In addition, the CET remains ranging from the top surface of the ferroelectric structure 108 to the bottom surface of the tunneling layer 104. The operation points Q4 are shown in the I-V curve 810d of the IGZO FE-FET 150, the P-V curve 820d of the MFS capacitor 140, the J-V curve 830d of the MIM selector 130, and the I-V curve 840d of the memory device.

Referring to FIG. 8J and FIG. 8K, the absolute value of the gate voltage VG is relatively larger than the absolute value of critical voltage VC and the absolute value of critical voltage VC is relatively larger than 0 V (i.e, 0 V<<|VC|<<<|VG|), the source voltage VSS applied to one of the contact structures 112 is 0 V, and the drain voltage VDD applied to another contact structure 112 is at a predetermined voltage (or logic high). In this condition, the MIM selector 130 is fully discharged, and the gate voltage VG modulation gets better again. As a result, MFS (or MIM) capacitor 140 is negatively charged. The same operations holds or repeats when the gate voltage VG is increased again.

FIG. 9A to FIG. 9W are schematic sectional views of various stages in a method of fabricating a memory device according to some embodiments of the present disclosure.

Referring to FIG. 9A and FIG. 9W, the wafer substrate SUB includes oxides layer (SiO₂) is provided. After forming the wafer substrate SUB, conformally depositing the metal layer 901 (e.g., TiN) on the wafer 900. After forming the metal layer 901, conformally depositing the nitride layer 902 (e.g., Si₃N₄) on the metal layer 901 by low pressure chemical vapor deposition (LPCVD), plasma enhanced CVD (PECVD), high-density plasma CVD (HDPCVD), etc. After forming the nitride layer 902, conformally depositing the photoresist 903 on the nitride layer 902. Etching the portion of the photoresist 903 to reveal the portion of the nitride layer 902. Etching the portions of the nitride layer 902 and the metal layer 901 straightly along the z-direction to form a plurality of revealing portions of the wafer substrate SUB. After forming a plurality of revealing portions of the wafer substrate SUB, conformally depositing the oxide layer 904 (e.g., TEOS). Subsequently, a planarization process (e.g., a chemical-mechanical planarization (CMP) process) is performed to remove excessive oxide layer 904 so that a top surface of the oxide layer 904 is coplanar (or aligned) with a top surface of the nitride layer 902. In addition, the metal layer 901 and the nitride layer 902 are surrounded by the oxide layer 904. After the planarization process, conformally depositing the metal layer 905 (e.g., TiN) on the nitride layer 902 and the oxide layer 904 to form an MIM structure, wherein the height of the metal layer 905 is larger than the height of the metal layer 901. After forming the metal layer 905, conformally depositing the oxide layer 906 (e.g., HfOₓ) on the metal layer 905, the oxide layer 907 including the non-oxide silicon ceramic (NOSC) on the oxide layer 906, and then covering the photoresist 908 on the oxide layer 907, sequentially. Pattering the photoresist 908 through a set(s) of photolithography and etching processes until forming a plurality of revealing portions of the oxide layer 907. The etching process may include a dry etching, a wet etching, or a combination thereof. After the etching process, a cleaning step may be optionally performed, for example to clean and remove the residue generated from the etching process. However, the disclosure is not limited thereto, and the etching process may be performed through any other suitable method. Etching the portions of the oxide layer 907, the oxide layer 906, and the metal layer 905 straightly along the z-direction sequentially to form a plurality of revealing portions of the oxide layer 904 and the nitride layer 902, so that sidewalls of the oxide layer 907, the oxide layer 906, and the metal layer 905 are aligned with each other. After the etching process, removing the photoresist 908 to form a revealing portion of the oxide layer 907. After forming a revealing portion of the oxide layer 907, conformally depositing the oxide layer 909 (e.g., TEOS) on the oxide layer 907, the oxide layer 906, the metal layer 905, and the nitride layer 902. Subsequently, a planarization process (e.g., a reference chemical-mechanical planarization (CMP) process) is performed to remove excessive oxide layer 909 to a predetermined thickness. After the CMP process, conformally depositing the photoresist 910 on the oxide layer 909. Pattering the photoresist 910 through a set(s) of photolithography and etching processes to form a plurality of revealing portions of the oxide layer 909 and a plurality of openings OP1 of the photoresist 910. The etching process may include a dry etching, a wet etching, or a combination thereof. After the etching process, a cleaning step may be optionally performed, for example to clean and remove the residue generated from the etching process. However, the disclosure is not limited thereto, and the etching process may be performed through any other suitable method. Etching the portions of the oxide layer 909 straightly along the z-direction to further form a plurality of openings OP2 of the oxide layer 909 and a plurality of revealing portions of the oxide layer 907, so that sidewalls of the oxide layer 909 and the photoresist 910 are aligned with each other. After the etching process, conformally depositing the metal layer 911 (e.g., TaN) on the photoresist 910, the oxide layer 909, and the oxide layer 907. In some embodiments, the width W1 of the metal layer 911 is larger than the width W2 of the plurality of openings OP2 of the oxide layer 909. After forming the metal layer 911, conformally depositing the metal layer 912 (e.g., W) on the metal layer 911 and filling the plurality of openings OP1 of the photoresist 910 and the plurality of openings OP2 of the oxide layer 909 with the metal layer 912. Subsequently, a planarization process (e.g., a stopping CMP process) is performed to remove excessive oxide layer 909, the metal layer 911, all of the photoresist 910, and the metal layer 912 to a predetermined thickness. As such, the memory device 900 is finished following the steps described in the text.

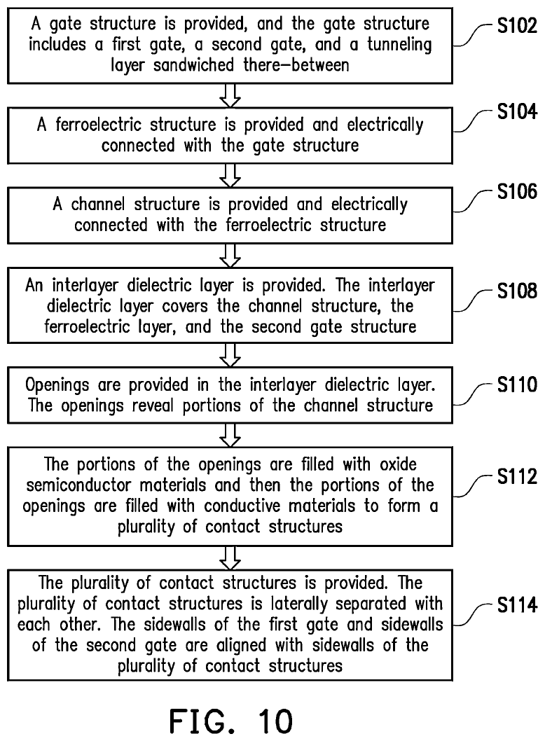

FIG. 10 illustrates a flowchart of a method of fabricating a memory device according to some embodiments of the present disclosure. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At step S102, a gate structure is provided, and the gate structure includes a first gate, a second gate, and a tunneling layer sandwiched there-between.

At step S104, a ferroelectric structure is provided and electrically connected with the gate structure.

At step S106, a channel structure is provided and electrically connected with the ferroelectric structure.

At step S108, an interlayer dielectric layer is provided. The interlayer dielectric layer covers the channel structure, the ferroelectric layer, and the second gate structure.

At step S110, openings are provided in the interlayer dielectric layer. The openings reveal portions of the channel structure.

At step S112, the portions of the openings are filled with oxide semiconductor materials and then the portions of the openings are filled with conductive materials to form a plurality of contact structures.

At step S114, the plurality of contact structures is provided. The plurality of contact structures is laterally separated with each other. The sidewalls of the first gate and sidewalls of the second gate are aligned with sidewalls of the plurality of contact structures.

In the above-mentioned embodiments, by supplying a tunneling dielectric between the side of the floating gate and the back gate, a flash-like memory structure may be obtained. Since the tunneling dielectric (or the tunnel oxide) is now not in contact with the channel as is the case in a standard flash device; therefore, the device properties are not compromised. The ferroelectric gate dielectric layer could potentially assist in retaining the charge in the floating gate and improve the retention of the memory cell.

Furthermore, due to the complementary state of the two transistors, the writing of the semiconductor device can be completed in one operation, and reading of the semiconductor device can be made easy by detecting a sign (positive or negative, e.g., a positive or negative difference in the voltage of two drain lines DL and DLB), rather than an absolute number, and the reading can be done differentially like in SRAM devices. Overall, an extremely compact and non-volatile differential pair design can be accomplished in the semiconductor device.

In accordance with some embodiments of the present disclosure, the memory device includes a gate structure, a ferroelectric structure over and electrically connected with the gate structure, a channel structure over the ferroelectric structure, and a plurality of contact structures over the channel structure. The gate structure includes a first gate as a back gate, a second gate as a floating gate, and a tunneling layer sandwiched there-between. The plurality of contact structures are laterally spaced apart with each other by a predetermined distance. In some embodiments, the sidewalls of the first gate are aligned with sidewalls of the plurality of contact structures.

In some embodiments, each contact structures comprises a sidewall structure covering the bottom and two lateral sides of each contact structures. In some embodiments, a material of the sidewall structure includes semiconductor oxide and in contact with the channel structure. In some embodiments, a material of the channel structure includes semiconductor oxide and in contact with the sidewall structure. In some embodiments, a material of the ferroelectric structure includes silicon doped hafnium oxide. In some embodiments, the plurality of contact structures over the channel structure and laterally separated by a first length, wherein the first length is the same as a length of the second gate structure. In some embodiments, the plurality of contact structures over the channel structure and laterally separated by a first length, wherein the first length is smaller than a length of the second gate structure. In some embodiments, sidewalls of the tunneling layer are aligned with sidewalls of the first gate and sidewalls of the second gate. In some embodiments, sidewalls of the ferroelectric structure are aligned with sidewalls of the first gate and sidewalls of the second gate. In some embodiments, a length of the channel structure is larger than a length of the ferroelectric structure. In some embodiments, a height of the first gate is larger than a height of the second gate. In some embodiments, a length of the tunneling layer is smaller than a second gate and the same as a length of the first gate. In some embodiments, the semiconductor device has a counter-clockwise current versus voltage hysteresis. In some embodiments, the floating gate comprises a triple dielectric structure includes oxide-nitride-oxide.

In accordance with some other embodiments of the present disclosure, a memory device includes a gate structure, a ferroelectric structure, a channel structure, and a plurality of contact structures. The gate structure includes a first gate, a second gate, and a tunneling layer sandwiched there-between. The ferroelectric structure includes indium gallium zinc oxide and electrically connected with the gate structure. The channel structure is electrically connected with the ferroelectric structure. The plurality of contact structures is electrically connected with the channel structure and laterally separated with each other. The sidewalls of the first gate are aligned with sidewalls of the plurality of contact structures and wherein sidewalls of the second gate are aligned with sidewalls of the channel structure.

In some embodiments, each contact structures comprises a sidewall structure covering the interface of the channel structure and two lateral sides of each contact structures, and wherein a material of the sidewall structure includes oxide semiconductor and in contact with the channel structure. In some embodiments, a length of the tunneling layer is smaller than a second gate and the same as a length of the first gate.

In accordance with yet another embodiment of the present disclosure, a method of fabricating a memory device is described. The method includes the following steps. A gate structure is formed on a dielectric layer. A ferroelectric structure, a channel structure, and a plurality of contact structures are sequentially formed along a first direction over the gate structure, wherein the gate structure comprises a first gate, a second gate, and a tunneling layer sandwiched there-between. The ferroelectric structure is electrically connected with the gate structure. The channel structure is electrically connected with the ferroelectric structure. The plurality of contact structures is laterally separated with each other. The sidewalls of the first gate and sidewalls of the second gate are aligned with sidewalls of the plurality of contact structures.

In some embodiments, the contact structures include an interlayer dielectric layer, openings in the interlayer dielectric layer, and sidewall structures. The interlayer dielectric layer covers the channel structure, the ferroelectric layer, and the second gate structure. The openings reveal portions of the channel structure. The portions of the openings are filled with oxide semiconductor materials and then the portions of the openings are filled with conductive materials to form contact structures. In some embodiments, part of the lateral edges of the sidewall structures are aligned with sidewalls of the tunneling gate, wherein a material of the channel structure includes oxide semiconductor and aligned with sidewalls the second gate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a gate structure over a substrate, wherein the gate structure comprises a first gate, a second gate, and a tunneling layer sandwiched there-between;
a ferroelectric structure over and electrically connected with the gate structure;
a channel structure over the ferroelectric structure; and
a plurality of contact structures over the channel structure and laterally spaced apart with each other by a predetermined distance, wherein sidewalls of the first gate are aligned with sidewalls of the plurality of contact structures.

2. The semiconductor device according to claim 1, wherein each contact structures comprises a sidewall structure covering the bottom and two lateral sides of each contact structures.

3. The semiconductor device according to claim 2, wherein a material of the sidewall structure includes semiconductor oxide and in contact with the channel structure.

4. The semiconductor device according to claim 1, wherein a material of the channel structure includes semiconductor oxide and in contact with the sidewall structure.

5. The semiconductor device according to claim 1, wherein a material of the ferroelectric structure includes silicon doped hafnium oxide.

6. The semiconductor device according to claim 1, wherein the plurality of contact structures over the channel structure and laterally separated by a first length, wherein the first length is the same as a length of the second gate structure.

7. The semiconductor device according to claim 1, wherein the plurality of contact structures over the channel structure and laterally separated by a first length, wherein the first length is smaller than a length of the second gate structure.

8. The semiconductor device according to claim 1, wherein sidewalls of the tunneling layer are aligned with sidewalls of the first gate and sidewalls of the second gate.

9. The semiconductor device according to claim 1, wherein sidewalls of the ferroelectric structure are aligned with sidewalls of the first gate and sidewalls of the second gate.

10. The semiconductor device according to claim 1, wherein a length of the channel structure is larger than a length of the ferroelectric structure.

11. The semiconductor device according to claim 1, wherein a height of the first gate is larger than a height of the second gate.

12. The semiconductor device according to claim 1, wherein a length of the tunneling layer is smaller than a second gate and the same as a length of the first gate.

13. The semiconductor device according to claim 1, wherein the semiconductor device has a counter-clockwise current versus voltage hysteresis.

14. The semiconductor device according to claim 1, wherein the floating gate comprises a triple dielectric structure includes oxide-nitride-oxide.

15. A memory device, comprising:
a gate structure, wherein the gate structure comprises a first gate, a second gate, and a tunneling layer sandwiched there-between;
a ferroelectric structure including indium gallium zinc oxide and electrically connected with the gate structure;
a channel structure electrically connected with the ferroelectric structure; and
a plurality of contact structures electrically connected with the channel structure and laterally separated with each other, wherein sidewalls of the first gate are aligned with sidewalls of the plurality of contact structures and wherein sidewalls of the second gate are aligned with sidewalls of the channel structure.

16. The memory device according to claim 15, wherein each contact structures comprises a sidewall structure covering the interface of the channel structure and two lateral sides of each contact structures, and wherein a material of the sidewall structure includes oxide semiconductor and in contact with the channel structure.

17. The memory device according to claim 15, wherein a length of the tunneling layer is smaller than a second gate and the same as a length of the first gate.

18. A method of fabricating a memory device, comprising:
forming a gate structure, wherein the gate structure comprises a first gate, a second gate, and a tunneling layer sandwiched there-between;
forming a ferroelectric structure electrically connected with the gate structure;
forming a channel structure electrically connected with the ferroelectric structure;
forming a plurality of contact structures laterally separated with each other, wherein sidewalls of the first gate and sidewalls of the second gate are aligned with sidewalls of the plurality of contact structures.

19. The method according to claim 18, wherein forming the contact structures comprises:
forming an interlayer dielectric layer covering the channel structure, the ferroelectric layer, and the second gate structure;
forming openings in the interlayer dielectric layer, wherein the openings reveal portions of the channel structure; and
filling portions of the openings with oxide semiconductor materials to form sidewall structures and then filling portions of the openings with conductive materials to form contact structures.

20. The method according to claim 18, wherein part of the lateral edges of the sidewall structures are aligned with sidewalls of the tunneling gate, wherein a material of the channel structure includes oxide semiconductor and aligned with sidewalls the second gate.
